(19) United States
(12) Patent Application Publication
(10) Pub. No.: US 2024/0276120 A1
(43) Pub. Date: Aug. 15, 2024

(54) SOLID-STATE IMAGING ELEMENT, ELECTRONIC DEVICE, AND METHOD FOR CONTROLLING SOLID-STATE IMAGING ELEMENT

(71) Applicant: Sony Semiconductor Solutions Corporation, Kanagawa (JP)

(72) Inventors: Mamoru Sato, Kanagawa (JP); Masaki Sakakibara, Kanagawa (JP); Toshiaki Ono, Kanagawa (JP)

(21) Appl. No.: 18/561,225

(22) PCT Filed: Dec. 28, 2021
(86) PCT No.: PCT/JP2021/048857

§ 371 Date: Nov. 15, 2023

(30) Foreign Application Priority Data
Jun. 30, 2021 (JP) 2021-108285

(51) Int. Cl. H04N 25/77; H04N 25/627

(52) U.S. Cl. CPC H04N 25/77; H04N 25/627

(57) ABSTRACT

To improve the image quality in a solid-state imaging element that performs CDS processing.

The solid-state imaging element includes an amplitude detection unit and a black spot prevention unit. The amplitude detection unit detects whether an output voltage that is a voltage of a vertical signal line for transmitting either a reset level at which a pixel is initialized or a signal level corresponding to an amount of light exceeds a predetermined determination threshold. The black spot prevention unit controls, when the output voltage exceeds the determination threshold, a first digital signal obtained by converting the reset level and a second digital signal obtained by converting the signal level to different values.

### TECHNICAL FIELD

The present technology relates to a solid-state imaging element. More specifically, the present invention relates to a solid-state imaging element that reads out signals multiple times, an electronic device, and a method for controlling the solid-state imaging element.

### BACKGROUND ART

Conventionally, an imaging device or the like performs correlated double sampling (CDS) processing that reads a signal from a pixel twice and obtains a difference between the signals. In this CDS processing, a signal when the floating diffusion region is initialized is read as a P-phase level, and a signal when the charge is transferred from the photodiode to the floating diffusion region is read as a D-phase level. By obtaining a difference between these P-phase level and D-phase level, fixed pattern noise is removed.

Here, when very strong light is incident, the difference data between the P-phase level and the D-phase level may be a value close to “0” even though the light is incident, this phenomenon is called the black spot phenomenon. Therefore, in order to set the P-phase level and the D-phase level to different values, for example, a differential amplification type of solid-state imaging element has been proposed in which the P-phase level is limited to the P-phase clip level or less and the D-phase level is limited to the D-phase clip level or less (see PTL 1, for example).

### CITATION LIST

### Patent Literature

### [PTL 1]:

WO 2017/179319

### SUMMARY

### Technical Problem

In the above-described conventional technology, the limitation of the P-phase level and the D-phase level to different clip levels prevents the black spot phenomenon. However, it is difficult to improve the image quality of captured image data with the solid-state imaging element as described above. For example, when the P-phase level and the D-phase level are limited to the clip levels, it is difficult to make the difference between the P-phase clip level and the D-phase clip level equal to or greater than a certain level, and as a result the dynamic range is limited. If the P-phase level and the D-phase level are not limited to the clip levels, the dynamic range can be extended, but the black spot phenomenon cannot be prevented, and thus the image quality may be reduced.

The present technology has been conceived in view of such circumstances, and an object thereof is to improve the image quality in a solid-state imaging element that performs the CDS processing.

### Solution to Problem

The present technology has been made to solve the above-described problems, and a first aspect thereof is a solid-state imaging element including: an amplitude detection unit that detects whether an output voltage that is a voltage of a vertical signal line for transmitting either a reset level at which a pixel is initialized or a signal level corresponding to an amount of light exceeds a predetermined determination threshold; and a black spot prevention unit that controls, when the output voltage exceeds the determination threshold, a first digital signal obtained by converting the reset level and a second digital signal by converting the signal level to different values, or a method for controlling the solid-state imaging element. This provides an effect of extending the dynamic range.

In this first aspect, the black spot prevention unit may include a clip unit that limits the output voltage to a value that does not exceed a predetermined clip level, and a pull-up circuit that controls, when the output voltage exceeds the determination threshold, the voltage to a value higher than the clip level within a period in which the signal level is converted. This provides an effect of preventing the black spot phenomenon.

In this first aspect, when the output voltage exceeds the determination threshold, the clip unit may limit the output voltage to a value that does not exceed the clip level. This provides an effect of preventing the black spot phenomenon.

In this first aspect, when enabled, the clip unit may limit the output voltage to a value that does not exceed the clip level. This provides an effect of preventing the black spot phenomenon.

In this first aspect, the pixel may include a signal pixel and a reference pixel that perform differential amplification, and the clip unit may be connected to a common signal line to which the signal pixel and the reference pixel are commonly connected. This provides an effect of differentially amplifying the signal.

In this first aspect, the clip unit may be connected to a node in the common signal line in the vicinity of the reference pixel. This provides an effect of suppressing characteristic fluctuations during bypass.

In this first aspect, the black spot prevention unit may include a clip unit that limits the output voltage to a value that does not exceed a predetermined clip level, and a count control unit that controls, when the output voltage exceeds the determination threshold, the second digital signal to a predetermined code. This provides an effect of preventing the black spot phenomenon.

In this first aspect, the black spot prevention unit may include a pull-up circuit that controls, when the output voltage exceeds the determination threshold, the voltage to a value higher than the clip level within a period in which the signal level is converted. This provides an effect of preventing the black spot phenomenon while suppressing an increase in circuit scale.

In this first aspect, the black spot prevention unit may include a clip unit that limits the output voltage to a value that does not exceed a predetermined clip level. This provides an effect of preventing the black spot phenomenon while suppressing an increase in circuit scale.

In this first aspect, the amplitude detection unit may include a capacitive element connected to a predetermined first node, a detector transistor that supplies a current to the first node when the output voltage exceeds a predetermined determination threshold, and a positive feedback logic unit that inverts a voltage of the first node and outputs the resulting voltage from the second node, and controls the voltage of the first node to a predetermined power supply voltage when a voltage of the second node is inverted. This provides an effect of improving an inversion speed of the voltage of the first node.

In this first aspect, the amplitude detection unit may include a capacitive element connected to a predetermined first node, a detector transistor that supplies a current to the first node when the output voltage exceeds the determination threshold, and a logic gate that inverts a voltage of the first node and outputs the resulting voltage from the second node. This provides an effect of reducing the circuit scale.

In this first aspect, the pixel may include a photodiode that generates a charge by photoelectric conversion, a transfer transistor that transfers the charge from the photodiode to a floating diffusion region, and a first reset transistor that initializes the floating diffusion region. This provides an effect of generating a reset level and a signal level.

In this first aspect, the pixel may further include a second reset transistor connected in parallel with the first reset transistor. This provides an effect of reducing the number of wiring lines.

In this first aspect, first and second vertical signal lines may be wired in each of a predetermined number of columns, a first pixel in the column may be connected to the first vertical signal line, and a second pixel in the column may be connected to the second vertical signal line. This provides an effect of improving the read speed.

In this first aspect, third and fourth vertical signal lines may be wired in each of the columns, a third pixel in the column may be connected to the third vertical signal line, and a fourth pixel in the column may be connected to the fourth vertical signal line. This provides an effect of further improving the read speed.

In this first aspect, a predetermined number of pixels may be connected to the vertical signal line, and a plurality of pixels among the predetermined number of pixels may share a floating diffusion region. This provides an effect of reducing the number of elements per pixel.

A second aspect of the present technology is an electronic device including: an amplitude detection unit that detects whether an output voltage that is a voltage of a vertical signal line for transmitting either a reset level at which a pixel is initialized or a signal level corresponding to an amount of light exceeds a predetermined determination threshold; a black spot prevention unit that controls, when the output voltage exceeds the determination threshold, a first digital signal obtained by converting the reset level and a second digital signal by converting the signal level to different values; and a column signal processing unit that obtains a difference between the first digital signal and the second digital signal. This provides an effect of performing the CDS processing.

### BRIEF DESCRIPTION OF DRAWINGS

FIG. 1 is a block diagram illustrating a configuration example of an electronic device according to a first embodiment of the present technology.

FIG. 2 is a block diagram illustrating a configuration example of a complementary MOS (CMOS) image sensor according to the first embodiment of the present technology.

FIG. 3 is a block diagram illustrating a configuration example of a pixel array unit and a column readout circuit unit according to the first embodiment of the present technology.

FIG. 4 is a circuit diagram illustrating a configuration example of the pixel array unit and the readout circuit according to the first embodiment of the present technology.

FIG. 5 is a circuit diagram illustrating a state of the readout circuit in an SF mode in the first embodiment of the present technology.

FIG. 6 is a circuit diagram illustrating a configuration example of an amplitude detection unit, a clip unit, and a pull-up circuit according to the first embodiment of the present technology.

FIG. 7 is a circuit diagram illustrating a configuration example of a column signal processing unit according to the first embodiment of the present technology.

FIG. 8 is a circuit diagram of a source follower readout configuration.

FIG. 9 is a circuit diagram of a differential amplification readout configuration.

FIG. 10 is a circuit diagram illustrating locations where noise is generated in the source follower readout configuration.

FIG. 11 illustrates examples of circuit diagrams with and without pixel sharing.

FIG. 12 is a circuit diagram illustrating locations where noise is generated in a configuration of differential amplification readout.

FIG. 13 is a circuit diagram illustrating an example of the state of the CMOS image sensor in a differential amplification readout configuration when initialized.

FIG. 14 is a circuit diagram of a CMOS image sensor according to a comparative example.

FIG. 15 is a timing chart illustrating an example of a readout operation of the CMOS image sensor according to the comparative example.

FIG. 16 illustrates an example of a level diagram in the comparative example.

FIG. 17 illustrates an example of a level diagram in the first embodiment of the present technology.

FIG. 18 is a timing chart illustrating an example of a readout operation in a differential mode in the first embodiment of the present technology.

FIG. 19 is a timing chart illustrating an example of a readout operation in the SF mode in the first embodiment of the present technology.

FIG. 20 is a timing chart illustrating an example of a readout operation in the differential mode when a large amount of light that does not cause overflow is incident in the first embodiment of the present technology.

FIG. 21 is a timing chart illustrating an example of a readout operation when overflow occurs in the first embodiment of the present technology.

FIG. 22 illustrates an example of a relationship between the voltage and the number of incident electrons in the first embodiment of the present technology.

FIG. 23 illustrates an example of a readout order of signal pixels according to the first embodiment of the present technology.

FIG. 24 is a flowchart illustrating an example of the operation of the CMOS image sensor according to the first embodiment of the present technology.

FIG. 25 is an example of a cross-sectional view of a front-illuminated CMOS image sensor according to the first embodiment of the present technology.

FIG. 26 is an example of a cross-sectional view of a back-illuminated CMOS image sensor according to the first embodiment of the present technology.

FIG. 27 illustrates an example of a stacked structure of the CMOS image sensor according to the first embodiment of the present technology.

FIG. 28 illustrates another example of a stacked structure of the CMOS image sensor according to the first embodiment of the present technology.

FIG. 29 is a circuit diagram illustrating a configuration example of an amplitude detection unit and a black spot prevention unit according to a second embodiment of the present technology.

FIG. 30 is a timing chart illustrating an example of a readout operation in a differential mode in the second embodiment of the present technology.

FIG. 31 is a circuit diagram illustrating a configuration example of a pixel array unit and a readout circuit according to a third embodiment of the present technology.

FIG. 32 is a circuit diagram illustrating a configuration example of a pixel array unit and a readout circuit according to a fourth embodiment of the present technology.

FIG. 33 is a circuit diagram illustrating a configuration example of an amplitude detection unit, a clip unit, and a pull-up circuit according to a fifth embodiment of the present technology.

FIG. 34 is a circuit diagram illustrating a configuration example of a pixel array unit and a readout circuit according to a sixth embodiment of the present technology.

FIG. 35 is a circuit diagram illustrating a configuration example of a pixel array unit and a readout circuit according to a seventh embodiment of the present technology.

FIG. 36 is a timing chart illustrating an example of a readout operation in a differential mode in the seventh embodiment of the present technology.

FIG. 37 is a circuit diagram illustrating a configuration example of a pixel array unit according to an eighth embodiment of the present technology.

FIG. 38 is a circuit diagram illustrating a configuration example of a pixel array unit and a readout circuit according to a ninth embodiment of the present technology.

FIG. 39 is a timing chart illustrating an example of a readout operation in a differential mode in the ninth embodiment of the present technology.

FIG. 40 is a circuit diagram illustrating a state of the readout circuit in an SF mode in the ninth embodiment of the present technology.

FIG. 41 is a timing chart illustrating an example of a readout operation in the SF mode in the ninth embodiment of the present technology.

FIG. 42 is a circuit diagram illustrating a configuration example of a pixel array unit according to a tenth embodiment of the present technology.

FIG. 43 is a circuit diagram illustrating a configuration example of a readout circuit according to the tenth embodiment of the present technology.

FIG. 44 is a block diagram illustrating a schematic configuration example of a vehicle control system.

FIG. 45 is an explanatory diagram illustrating an example of installation positions of imaging units.

### DESCRIPTION OF EMBODIMENTS

Modes for carrying out the present technology (hereinafter also referred to as “embodiments”) will be described below. The description will be given in the following order.
1. First embodiment (example of clipping and pull-up when amplitude is detected)
2. Second embodiment (example of clipping when amplitude is detected and controlling a counter)
3. Third embodiment (example of pull-up when amplitude is detected)
4. Fourth embodiment (example of clipping when amplitude is detected)
5. Fifth embodiment (example of pull-up when amplitude is detected and controlling the clip unit independently)
6. Sixth embodiment (example of clipping and pull-up when amplitude is detected to reduce wires)
7. Seventh embodiment (example of eliminating the positive feedback logic unit, and clipping and pull-up when amplitude is detected)
8. Eighth embodiment (example of sharing a floating diffusion region, and clipping and pull-up when amplitude is detected)
9. Ninth embodiment (example of adding a reset transistor, and clipping and pull-up when amplitude is detected)
10. Tenth embodiment (example of clipping and pull-up when amplitude is detected to improve the readout speed)
11. Application example to moving body

### 1. First Embodiment

### [Configuration Example of Electronic Device]

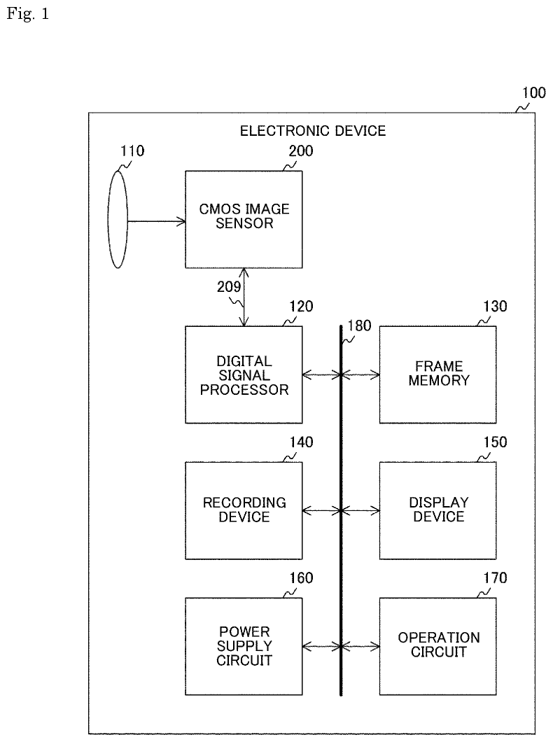

FIG. 1 is a block diagram illustrating a configuration example of an electronic device 100 according to a first embodiment. The electronic device 100 is a device that captures image data. The electronic device 100 includes an imaging lens 110, a CMOS image sensor 200, a digital signal processor 120, a frame memory 130, a recording device 140, a display device 150, a power supply circuit 160, an operation circuit 170, and a bus 180. As the electronic device 100, a digital camera, a mobile device having a camera module, and the like may be used.

The imaging lens 110 collects light and guides the light to the CMOS image sensor 200. The CMOS image sensor 200 photoelectrically converts the light from the imaging lens 110 to generate image data under the control of the digital signal processor 120. This CMOS image sensor 200 supplies the image data to the digital signal processor 120 via a signal line 209.

The digital signal processor 120 performs predetermined image processing on the image data. This digital signal processor 120 controls the CMOS image sensor 200 to generate the image data in response to an operation such as pressing a shutter button. The digital signal processor 120 then uses the frame memory 130 as necessary to perform various image processing on the image data. As the image processing, demosaic processing, white balance processing, synthesis processing, and the like may be performed. The digital signal processor 120 supplies the image data on which the image processing has been performed to the recording device 140 via the bus 180 for recording. The digital signal processor 120 also causes the display device 150 to display the image data in accordance with a user's operation.

The frame memory 130 holds the image data (frame). The recording device 140 records the image data. The display device 150 displays the image data. The power supply circuit 160 supplies power to circuits in the electronic device 100.

The operation circuit 170 generates an operation signal in accordance with a user's operation and supplies the operation signal to the digital signal processor 120. The bus 180 is a common path for interchanging signals between the digital signal processor 120, the frame memory 130, the recording device 140, the display device 150, the power supply circuit 160, and the operation circuit 170.

### [Configuration Example of Solid-State Imaging Element]

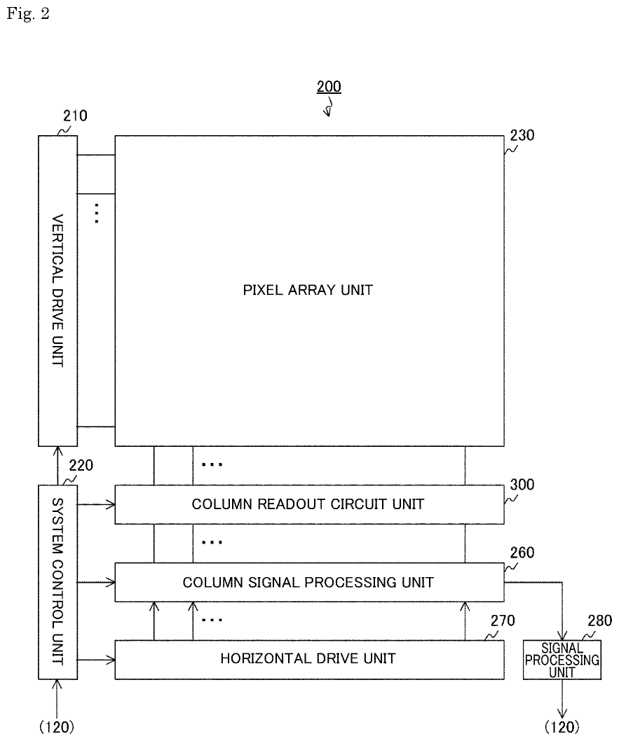

FIG. 2 is a system configuration diagram illustrating a configuration example of the CMOS image sensor 200 serving as a solid-state imaging element to which the present invention is applied. This CMOS image sensor 200 (solid-state imaging element) includes a vertical drive unit 210, a system control unit 220, a pixel array unit 230, a column readout circuit unit 300, a column signal processing unit 260, a horizontal drive unit 270, and a signal processing unit 280. These circuits in the CMOS image sensors 200 (the vertical drive unit 210 and the system control unit 220) are formed on the same laminated semiconductor substrate (chip) or a plurality of laminated semiconductor substrates (chips) electrically connected to each other.

In the pixel array unit 230, unit pixels (hereinafter referred to as “effective unit pixels”) that each include a photoelectric conversion element capable of photoelectrically converting and accumulating an amount of charge corresponding to an amount of incident light and outputting the amount of charge as a signal are arrayed two-dimensionally in a matrix. In addition to the effective unit pixels, the pixel array unit 230 may include regions in which dummy unit pixels having a structure without photodiodes for performing photoelectric conversion, and light-shielding unit pixels that shield a light-receiving surface from light to block the light entering from the outside, which are otherwise equivalent to the effective pixels, are arranged two-dimensionally in a matrix.

Hereinafter, the photo-charge of an amount of charge corresponding to an amount of incident light may be simply referred to as a “charge” and the unit pixel may be simply referred to as a “pixel”.

Furthermore, in the pixel array unit 230, for the matrix of pixel arrays, a pixel drive line is formed for each row in the lateral direction in the drawing (the direction in which the pixels are arranged in a pixel row), and a vertical pixel wire is formed for each column in the longitudinal direction in the drawing (the direction in which the pixels are arranged in a pixel column). One end of the pixel drive line is connected to an output terminal of the vertical drive unit corresponding to each row.

The column readout circuit unit 300 includes at least a circuit that supplies a constant current to the pixels in a selected row in the pixel array unit 230 for each column, a current mirror circuit, a switching switch for a readout pixel, and the like. The column readout circuit unit 300 constitutes an amplifier along with transistors in a selected pixel in the pixel array unit 230, converts a photo-charge signal into a voltage signal, and outputs the voltage signal to the vertical pixel wire.

The vertical drive unit 210 is a pixel drive unit that includes a shift register, an address decoder, and the like to drive all the pixels of the pixel array unit 230 simultaneously or row by row. Although not specifically illustrated in the drawings, the vertical drive unit 210 includes a readout scanning system and a sweep scanning system, or a batch sweep and batch transfer.

The readout scanning system sequentially selectively scans the unit pixels of the pixel array unit row by row in order to read out signals from the unit pixels. In the case of row drive (rolling shutter operation), the sweep scanning is performed ahead of the readout scanning by the shutter speed time for a readout row to be readout scanned by the readout scanning system. In the case of global exposure (global shutter operation), the batch sweeping is performed ahead of the batch transfer by the shutter speed time. By this sweeping, unnecessary charges are swept out (reset) from the photoelectric conversion elements of the unit pixels in the readout row. The sweep out (reset) of unnecessary charges is a so-called electronic shutter operation. Here, the electronic shutter operation refers to an operation of discarding unnecessary photo-charges accumulated in the photoelectric conversion elements immediately before and starting new exposure (starting accumulation of photo-charges). The signal read out by the readout operation through the readout scanning system corresponds to an amount of incident light after the previous readout operation or the electronic shutter operation. In the case of row drive, a period from the readout timing of the previous readout operation or the sweep timing of the electronic shutter operation to the readout timing of the current readout operation is an accumulation time (exposure time) of photo-charges in a unit pixel. In the case of global exposure, a time from the batch sweeping to the batch transfer is an accumulation time (exposure time).

A pixel signal output from each unit pixel in a pixel row selected and scanned by the vertical drive unit 210 is supplied to the column signal processing unit 260 through each of the vertical pixel wires. The column signal processing unit 260 performs predetermined signal processing on the pixel signals output from the unit pixels in the selected row through the vertical pixel wire for each pixel column of the pixel array unit and temporarily holds the pixel signals on which the signal processing has been performed.

Specifically, the column signal processing unit 260 performs at least noise removal processing, for example, correlated double sampling (CDS) processing as signal processing. This correlated double sampling performed by the column signal processing unit 260 removes fixed pattern noise specific to pixels such as reset noise and variations in threshold of an amplifier transistor. In addition to the noise removal processing, the column signal processing unit may have an analog-to-digital (AD) conversion function to output a signal level as a digital signal, for example.

The horizontal drive unit 270 includes a shift register, an address decoder, and the like to sequentially select the unit circuits corresponding to the pixel columns of the column signal processing unit 260. The pixel signals on which the signal processing has been performed by the column signal processing unit 260 are sequentially output to the signal processing unit by the selective scanning of the horizontal drive unit 270.

The system control unit 220 includes a timing generator that generates various timing signals, and the like. The system control unit 220 controls the driving of the vertical drive unit 210, the column signal processing unit 260, the horizontal drive unit 270, and the like based on the various timing signals generated by the timing generator.

The CMOS image sensor 200 further includes the signal processing unit 280. The signal processing unit 280 has at least an addition processing function to perform various signal processing such as addition processing on the pixel signals output from the column signal processing unit 260. The signal processing unit 280 may be an external signal processing unit provided on a substrate different from the CMOS image sensor 200, such as a DSP (Digital Signal Processor) or software processing, or may be mounted on the same substrate as the CMOS image sensor 200.

### [Configuration Example of Pixel Array Unit and Column Readout Circuit Unit]

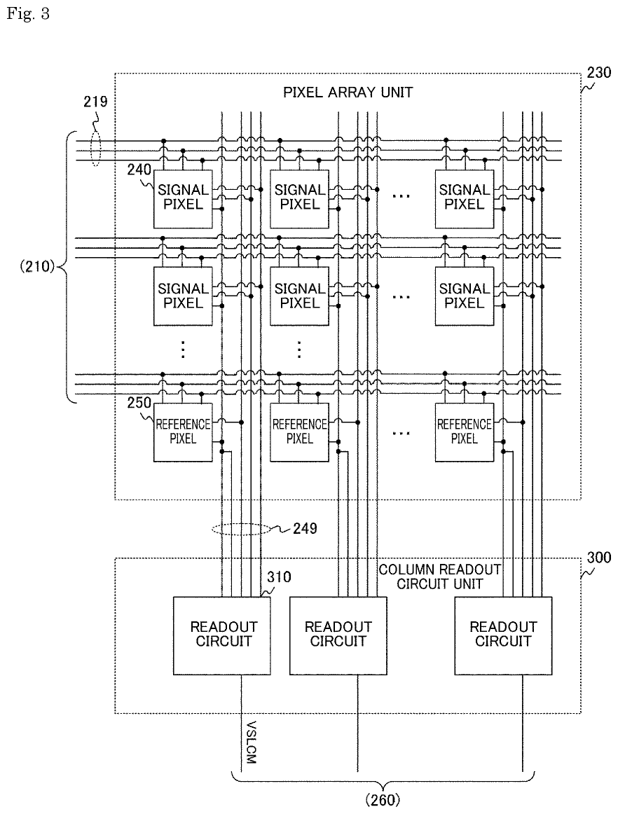

FIG. 3 is a block diagram illustrating a configuration example of the pixel array unit 230 and the column readout circuit unit 300 according to the first embodiment of the present technology.

The pixels in the pixel array unit 230 include signal pixels 240 and reference pixels 250. The signal pixel 240 is a pixel to be read out. The reference pixel 250 is a pixel that supplies a reference voltage in a differential amplifier circuit that includes the signal pixel 240 and the reference pixel 250.

In the pixel array unit 230, for example, a plurality of signal pixels 240 are arranged in a two-dimensional lattice, and one reference pixel 250 is arranged corresponding to each column of signal pixels 240. A row in which the signal pixels 240 are arranged is referred to as a “readout row”, and a row in which the reference pixels 250 are arranged is referred to as a “reference row”.

In the column readout circuit unit 300, a readout circuit 310 is arranged for each column. The readout circuit 310 supplies a pixel signal to the column signal processing unit 260 via a comparator-side vertical signal line VSLCM.

In the pixel array unit 230, a pixel drive line 219 including three signal lines is wired for each row, and a vertical pixel wire 249 including five signal lines is wired for each column. Each of the signal pixels 240 and the reference pixels 250 is connected to the vertical drive unit 210 via the corresponding pixel drive line 219 and connected to the readout circuit 310 via the corresponding vertical pixel wire 249.

### [Configuration Example of Readout Circuit]

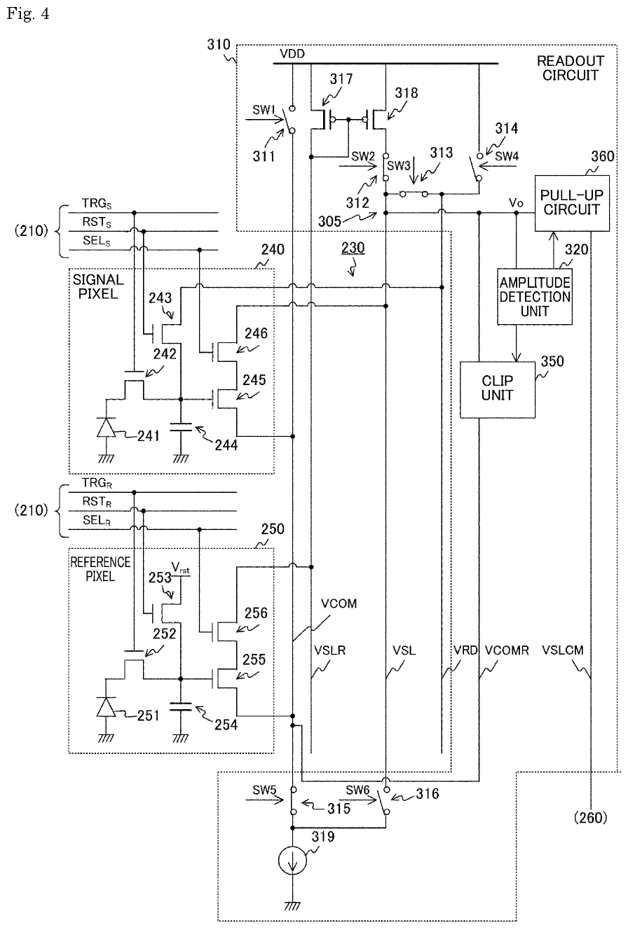

FIG. 4 is a circuit diagram illustrating a configuration example of the pixel array unit 230 and the readout circuit 310 according to the first embodiment of the present technology.

In the pixel array unit 230, five signal lines consisting of a common signal line VCOM, a reference-side common signal line VCOMR, a reference-side vertical signal line VSLR, a vertical signal line VSL, and a reset bias line VRD are wired vertically for each column.

The signal pixel 240 includes a photodiode 241, a transfer transistor 242, a reset transistor 243, a floating diffusion region 244, an amplifier transistor 245, and a selector transistor 246.

The reset transistor 243 turns on/off discharge of charge accumulated in the floating diffusion region 244 according to a drive signal RST_{S} supplied from the vertical drive unit 210. When a drive signal RST_{S} with high level is supplied to the reset transistor 243, the floating diffusion region 244 is clamped to a voltage applied through the reset bias line VRD, and the charge accumulated in the floating diffusion region 244 are discharged (reset). When a drive signal RST_{S} with low level is supplied, the floating diffusion region 244 is electrically disconnected from the reset bias line VRD and becomes floating.

On the other hand, the photodiode 241 photoelectrically converts incident light to generate and accumulate charge corresponding to the amount of light. The transfer transistor 242 turns on/off the transfer of charge from the photodiode 241 to the floating diffusion region 244 according to a drive signal TRG_{S} supplied from the vertical drive unit 210. For example, when a drive signal TRG_{S} with high level is supplied, the transfer transistor 242 transfers the charge accumulated in the photodiode 241 to the floating diffusion region 244, and when a drive signal TRG_{S} with low level is supplied, the transfer transistor 242 stops the transfer of the charge. While the transfer transistor 242 stops the transfer of the charge to the floating diffusion region 244, the photoelectrically converted charge is accumulated in the photodiode 241.

The floating diffusion region 244 has a function of accumulating the charge transferred from the photodiode 241 through the transfer transistor 242, and in a floating state in which the reset transistor 243 is off, the electric potential of the floating diffusion region 244 is modulated according to the amount of charge accumulated.

The amplifier transistor 245 functions as an amplifier in which an input signal is a change in the electric potential of the floating diffusion region 244 connected to the gate of the amplifier transistor 245, and an output voltage signal of the amplifier transistor 245 is output to the vertical signal line VSL through the selector transistor 246.

The selector transistor 246 turns on/off the output of the voltage signal from the amplifier transistor 245 to the vertical signal line VSL according to a drive signal SEL_{S} supplied from the vertical drive unit 210. For example, when a drive signal SEL_{S} with high level is supplied, the selector transistor 246 outputs a voltage signal to the vertical signal line VSL, and when a drive signal SEL_{S} with low level is supplied, the selector transistor 246 stops the output of the voltage signal. Accordingly, in the vertical signal line VSL to which a plurality of pixels are connected, only the output of a selected pixel can be extracted.

Thus, the signal pixel 240 is driven according to the drive signal TRG_{S}, the drive signal RST_{S}, and the drive signal SEL_{S}, which are supplied from the vertical drive unit 210.

The level of the pixel signal when the floating diffusion region 244 is initialized is referred to as the “P-phase level” or “reset level”. The level of the pixel signal corresponding to the amount of light when the charge is transferred from the photodiode 241 to the floating diffusion region 244 is referred to as the “D-phase level” or the “signal level”.

The reference pixel 250 includes a photodiode 251, a transfer transistor 252, a reset transistor 253, a floating diffusion region 254, an amplifier transistor 255, and a selector transistor 256. The connection configuration of these elements is similar to that of the signal pixel 240. However, the vertical drive unit 210 supplies a drive signal TRG_{R}, a drive signal RST_{R}, and a drive signal SEL_{R}. The drain of the reset transistor 253 is connected to a reset power supply voltage Vᵣₛₜ, and the drain of the selector transistor 256 is connected to the reference-side vertical signal line VSLR.

The sources of the amplifier transistors 245 and 255 are connected to the common signal line VCOM.

The readout circuit 310 also includes switches 311 to 316, p-channel metal oxide semiconductor (pMOS) transistors 317 and 318, and a tail current source 319. Further, the readout circuit 310 includes an amplitude detection unit 320, a clip unit 350, and a pull-up circuit 360.

The gate of the pMOS transistor 317 is connected to the gate of the pMOS transistor 318. The drain of the pMOS transistor 317 is connected to its own gate and the reference vertical signal line VSLR, and the source is connected to a power supply voltage VDD. On the other hand, the drain of the pMOS transistor 318 is connected to the vertical signal line VSL through the switch 312, and the source is connected to the power supply voltage VDD. With this configuration, the pMOS transistor 317 outputs a reference current, and the pMOS transistor 318 outputs a signal current close to the reference current. Such a circuit is called a current mirror circuit.

The switch 311 opens and closes the path between the power supply voltage VDD and the common signal line VCOM according to a control signal SW1 from the system control unit 220. The switch 312 opens and closes the path between the pMOS transistor 318 and the vertical signal line VSL according to a control signal SW2 from the system control unit 220.

The switch 313 opens and closes the path between the vertical signal line VSL and the reset bias line VRD according to a control signal SW3 from the system control unit 220. The switch 314 opens and closes the path between the power supply voltage VDD and the reset bias line VRD according to a control signal SW4 from the system control unit 220.

The switch 315 opens and closes the path between the common signal line VCOM and the tail current source 319 according to a control signal SW5 from the system control unit 220. The switch 316 opens and closes the path between the vertical signal line VSL and the tail current source 319 according to a control signal SW6 from the system control unit 220.

The tail current source 319 controls constant the current from the common signal line VCOM and the vertical signal line VSL. The tail current source 319 is realized by, for example, an n-channel MOS (nMOS) transistor in which a predetermined bias voltage is applied to the gate.

Here, the CMOS image sensor 200 is set to either a differential mode or an SF mode. The differential mode is a mode in which the CMOS image sensor 200 generates a signal obtained by amplifying a difference between the pixel signals of a pair of pixels (i.e., by differential amplification). On the other hand, the SF mode is a mode in which a source follower readout circuit is formed to output the pixel signals without differential amplification.

In the differential mode, the gain for an image signal can be increased to greatly increase the conversion efficiency, but the operating point is narrow, making it difficult to extend the dynamic range. Accordingly, the differential mode is suitable for imaging in dark places, while the SF mode is suitable for imaging in bright places. Therefore, for example, a circuit external to the CMOS image sensor 200 measures the amount of ambient light, and an instruction for the differential mode is issued if the amount of light measured is smaller than a predetermined value, and an instruction for the SF mode is issued if the amount of light measured is equal to or greater than the predetermined value. The CMOS image sensor 200 itself may measure the light to set the mode.

When the differential mode is set, the system control unit 220 closes the switches 312, 313, and 315 and opens the switches 311, 314, and 316 by the control signals SW1 to SW6. Accordingly, a differential amplifier circuit is formed, and a pixel signal obtained by differentially amplifying the signals of the reference pixel 250 and the signal pixel 240 is output. This figure illustrates a state of the readout circuit 310 when the differential mode is set.

In the differential mode, the amplitude detection unit 320 detects whether or not an output voltage Vo (in other words, an amplitude) of an output node 305 of the vertical signal line VSL for transmitting the P-phase level or the D-phase level exceeds a predetermined determination threshold. This amplitude detection unit 320 supplies the detection result to the clip unit 350 and the pull-up circuit 360.

When the output voltage Vo (amplitude) exceeds the determination threshold in the differential mode, the clip unit 350 limits the output voltage Vo to a value that does not exceed a predetermined clip level. This clip unit 350 is arranged between the vertical signal line VSL and the common signal line VCOM to open and close the path between these signal lines. When the output voltage Vo is equal to or less than the determination threshold in the differential mode, the clip unit 350 is in an open state. Meanwhile, no current flows through the clip unit 350, and the signal current flows from the output node 305 to the common signal line VCOM through the amplifier transistor 245 of the signal pixel 240.

When the output voltage Vo exceeds the determination threshold in the differential mode, the clip unit 350 enters a closed state. As a result, the vertical signal line VSL and the common signal line VCOM are connected to each other (bypassing), so that the signal current flows through the clip unit 350. Since the current (reference current+signal current) supplied by the tail current source 319 is constant, no current flows through the amplifier transistor 245. Accordingly, the output voltage Vo stops rising and is fixed (in other words, clipped) at the clip level. In the SF mode, the clip unit 350 is in an open state and the output voltage Vo is not clipped.

In this manner, with the configuration in which the clip unit 350 provides bypass to the common signal line VCOM, a current obtained by combining the currents of the signal pixel and the reference pixel flows in the common signal line VCOM for a low-illuminance signal with a level that the clip unit 350 does not bypass. This non-bypass operation-state is hereinafter referred to as “normal imaging” in order to be distinguished from the bypass state.

The clip unit 350 is connected to a node in the vicinity of the reference pixel 250 on the common signal line VCOM via the reference-side common signal line VCOMR. Accordingly, the current flowing through the clip unit 350 joins the common signal line VCOM near the reference pixel 250.

As will be described later, the reference-side common signal line VCOMR can also be connected to a node in the vicinity of the switch 315 without being wired in the pixel array unit 230. However, with this configuration, the clip unit 350 takes in the current of the signal pixel 240 during bypass, so that the current flowing through the common signal line VCOM in the pixel array unit 230 is only the reference pixel component. As a result, the amount of IR drop of the common signal line VCOM changes, and the characteristics vary as compared to the case of the normal imaging.

As illustrated by way of example in the same figure, the current taken by the clip unit 350 joins the common signal line VCOM near the reference pixel to match the amount of IR drop of the common signal line VCOM in the pixel array unit 230 during bypass with that in the case of the normal imaging, so that it is possible to suppress the variations in characteristics.

When the output voltage Vo exceeds the determination threshold in the differential mode, the pull-up circuit 360 controls (in other words, pulls up) the voltage to be output to a value higher than the clip level within a period in which AD conversion is performed on the D-phase level (signal level). The pull-up circuit 360 supplies the pulled-up voltage to the column signal processing unit 260 via the comparator-side vertical signal line VSLCM. When the output voltage Vo is equal to or less than the determination threshold in the differential mode or when it is in the SF mode, the pull-up circuit 360 does not pull up the output voltage Vo and supplies the output voltage Vo to the column signal processing unit 260 as it is.

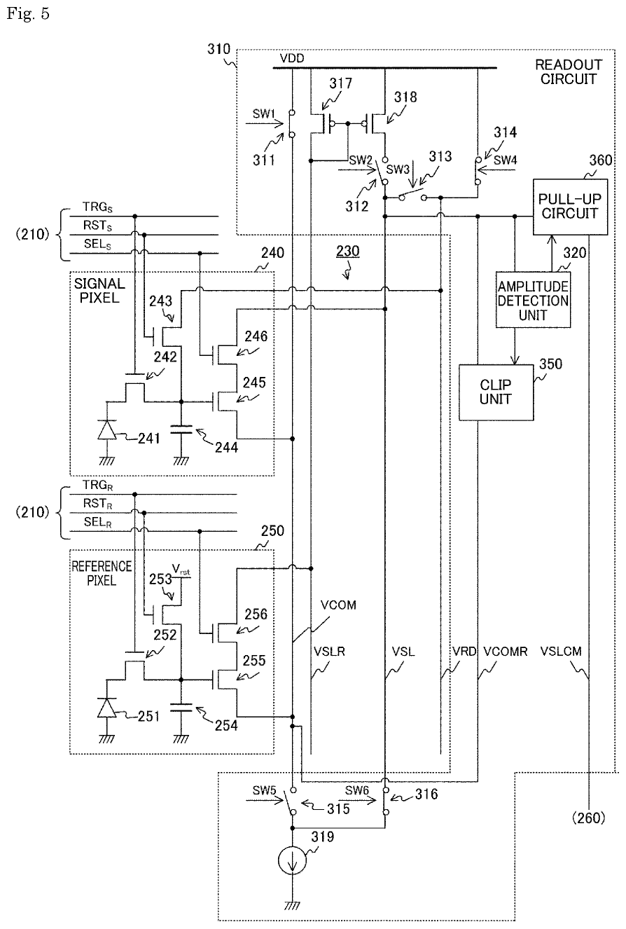

FIG. 5 is a circuit diagram illustrating a state of the readout circuit in the SF mode according to the first embodiment of the present technology. When the SF mode is set, the system control unit 220 opens the switches 312, 313, and 315 and closes the switches 311, 314, and 316 by the control signals SW1 to SW6. These controls connect the vertical signal line VSL to the tail current source 319. The power supply voltage VDD is applied to the reset bias line VRD, which is connected to the floating diffusion region 244 of the selected signal pixel 240 (that is, the input terminal of the amplifier transistor 245 on the readout side) through the reset transistor 243 in the pixel unit. In the readout circuit 310, the power supply voltage VDD is applied to the common signal line VCOM, which is the drain of the amplifier transistor 245 of the signal pixel 240. An output signal is taken out from the vertical signal line VSL. At this time, the reference pixel 250, the amplitude detection unit 320, the clip unit 350, and the pull-up circuit 360 are inactive.

### [Configuration Example of Amplitude Detection Unit and Black Spot Prevention Unit]

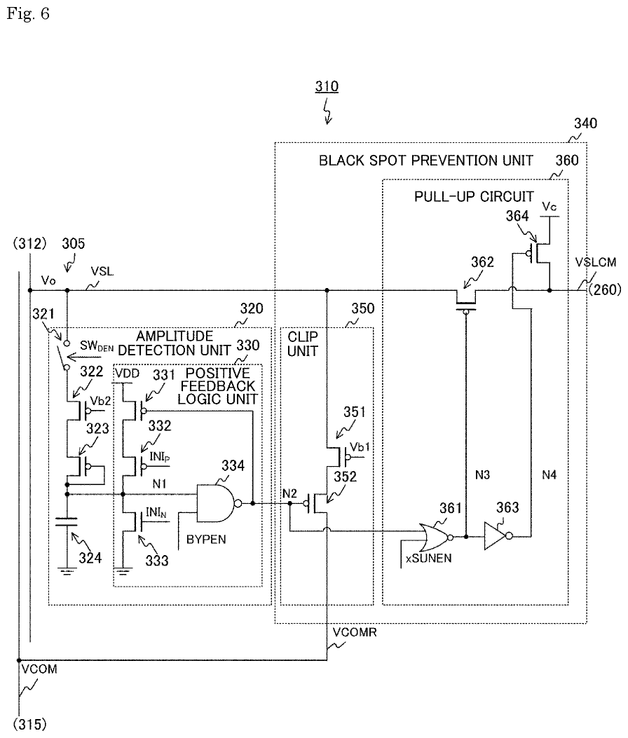

FIG. 6 is a circuit diagram illustrating a configuration example of the amplitude detection unit 320, the clip unit 350, and the pull-up circuit 360 according to the first embodiment of the present technology. The clip unit 350 and the pull-up circuit 360 function as a black spot prevention unit 340 that prevents the black spot phenomenon.

The amplitude detection unit 320 includes a switch 321, pMOS transistors 322 and 323, a capacitive element 324, and a positive feedback logic unit 330. The positive feedback logic unit 330 includes pMOS transistors 331 and 332, an nMOS transistor 333, and a NAND (logical NAND) gate 334.

The clip unit 350 also includes pMOS transistors 351 and 352. The pull-up circuit 360 includes a NOR gate 361, a pMOS transistor 362, an inverter 363, and a pMOS transistor 364.

In the amplitude detection unit 320, the switch 321 opens and closes the path between the vertical signal line VSL and the pMOS transistor 322 according to a control signal SW_{DEN} from the system control unit 220. For example, when the control signal SW_{DEN} is at high level, the amplitude detection unit 320 is enabled and the switch 321 is in a closed state. On the other hand, when the control signal SW_{DEN} is at low level, the switch 321 is in an open state.

The pMOS transistors 322 and 323 are connected in series between the switch 321 and the capacitive element 324. A predetermined bias voltage Vb2 is input to the gate of the pMOS transistor 322, and the gate and drain of the pMOS transistor 323 are short-circuited (in other words, diode-connected).

The capacitive element 324 is inserted between the pMOS transistor 322 and a ground node. A node N1, which is a connection node between the pMOS transistor 322 and the capacitive element 324, is connected to the positive feedback logic unit 330. The node N1 is an example of a first node described in the claims.

In the positive feedback logic unit 330, the pMOS transistors 331 and 332 are connected in series between the power supply voltage VDD and the node N1 with the pMOS transistor 331 on the power supply side. The gate of the pMOS transistor 331 is connected to the output of the NAND gate 334. A control signal INI_{P} from the system control unit 220 is input to the gate of the pMOS transistor 332.

The nMOS transistor 333 is inserted between the node N1 and the ground node. A control signal INI_{N} from the system control unit 220 is input to the gate of the nMOS transistor 333.

The NAND gate 334 outputs a logical NAND of the node N1 and a control signal BYPEN from the system control unit 220 to the gate of the pMOS transistor 331, the clip unit 350, and the pull-up circuit 360. This output node is referred to as a node N2. The node N2 is an example of a second node described in the claims.

With the above-described circuit configuration, the gate-source voltage of the pMOS transistor 322 increases as the vertical signal line VSL rises when the control signal SW_{DEN} is at high level, and when that voltage exceeds the threshold voltage, the pMOS transistor 322 transitions from off-state to on-state. When the pMOS transistor 322 enters on-state, the pMOS transistor 322 supplies a current to the capacitive element 324, and the node N1 is inverted from low level to high level. At this time, since the diode-connected pMOS transistor 323 is inserted between the pMOS transistor 322 and the node N1, even if the vertical signal line VSL varies due to noise or the like, the current of the node N1 does not flow backward and thus flips back to low level again. The pMOS transistor 322 is an example of a detector transistor described in the claims.

When the control signal BYPEN is at high level, the clip function is enabled and the voltage obtained by inverting the node N1 is output from the node N2. Here, when the node N1 is inverted from low level to high level, the node N2 is inverted from high level to low level. Thus, the node N2 of the amplitude detection unit 320 indicates a result of determining the amplitude, and is inverted from high level to low level when the amplitude of the vertical signal line VSL exceeds the determination threshold. The determination threshold for the inversion of each of the nodes N1 and N2 is proportional to the bias voltage Vb2.

In the positive feedback logic unit 330, the result of the node N2 is fed back to the gate of the pMOS transistor 331 on the node N1 side, and when the node N2 is inverted, the node N1 is controlled to the power supply voltage VDD. Therefore, even if the level of the vertical signal line VSL is close to the determination threshold and the charging of the node N1 is slow, the inversion speed of the node N1 can be sufficiently increased.

In the clip unit 350, the pMOS transistors 351 and 352 are connected in series between the vertical signal line VSL and the reference-side common signal line VCOMR. A predetermined bias voltage Vb1 is input to the gate of pMOS transistor 351, and the gate of pMOS transistor 352 is connected to the node N2.

With the above-described circuit configuration, when the node N2 is inverted from high level to low level, the pMOS transistor 352 transitions from off-state to on-state. When the pMOS transistor 352 is in on-state, the gate-source voltage of the pMOS transistor 351 increases as the vertical signal line VSL rises, and when that voltage exceeds the threshold voltage, the pMOS transistor 351 transitions from off-state to on-state. When the pMOS transistors 351 and 352 enters on-state, the output node 305 of the vertical signal line VSL and the common signal line VCOM bypass, and the output voltage Vo stops rising and is fixed at the clip level. This clip level is proportional to the bias voltage Vb1.

In the pull-up circuit 360, the pMOS transistor 362 is inserted between the vertical signal line VSL and the reference-side vertical signal line VSLR. The pMOS transistor 364 is also inserted between a voltage Vc higher than the clip level and the comparator-side vertical signal line VSLCM.

The NOR gate 361 outputs a logical NOR of the node N2 and a control signal xSUNEN from the system control unit 220 to the gate of the pMOS transistor 362 and the inverter 363. This output node is referred to as a node N3.

The inverter 363 inverts the level of the node N3 and outputs the inverted level to the gate of pMOS transistor 364. This output node is referred to as a node N4.

With the above-described circuit configuration, the pull-up function is enabled when the control signal xSUNEN is at low level, and the node N3 turns to high level when the node N2 is inverted to low level. When the node N3 turns to high level, the pMOS transistor 362 transitions from on-state to off-state, and the node N4 turns to low level. When the node N4 turns to low level, the pMOS transistor 364 transitions from off-state to on-state. When the pMOS transistor 364 enters on-state, the comparator-side vertical signal line VSLCM is pulled up to the voltage Vc higher than the clip level, and the voltage Vc is output to the column signal processing unit 260 as the output voltage Vo (D-phase level).

Here, when an extremely large amount of light is incident, such as when an image is captured under the sun, a large amount of charge is generated in the photodiode 241 in the signal pixel 240, which may be beyond the electric potential of the transfer transistor 242 and leak into the floating diffusion region. As a result, the output voltage Vo (P-phase level) may increase.

If the black spot prevention unit 340 is absent, the P-phase level may rise to a value close to the power supply voltage VDD. After this P-phase level, the D-phase level is generated. Under high illuminance, the D-phase level is also generated having a value close to the power supply voltage VDD. When the P-phase level and the D-phase level are equal in this way, the difference between them becomes close to “0” in the CDS processing, and black level pixel data is output even though strong light is incident. In other words, the black spot phenomenon occurs.

However, when the P-phase level exceeds the determination threshold, the clip unit 350 fixes the P-phase level at the clip level, and then the pull-up circuit 360 pulls up the D-phase level to Vc, which is higher than the clip level. As a result, a digital signal obtained by converting the P-phase level and a digital signal obtained by converting the D-phase level have different values, so that the black spot phenomenon can be prevented.

When the amplitude detection unit 320 detects whether or not the output voltage Vo exceeds a predetermined determination threshold, and when the output voltage Vo exceeds the determination threshold, the black spot prevention unit 340 operates. This makes it possible to provide a wider dynamic range than in the case where the amplitude detection unit 320 is absent. The reason why the dynamic range is extended will be described later.

### [Configuration Example of Column Signal Processing Unit]

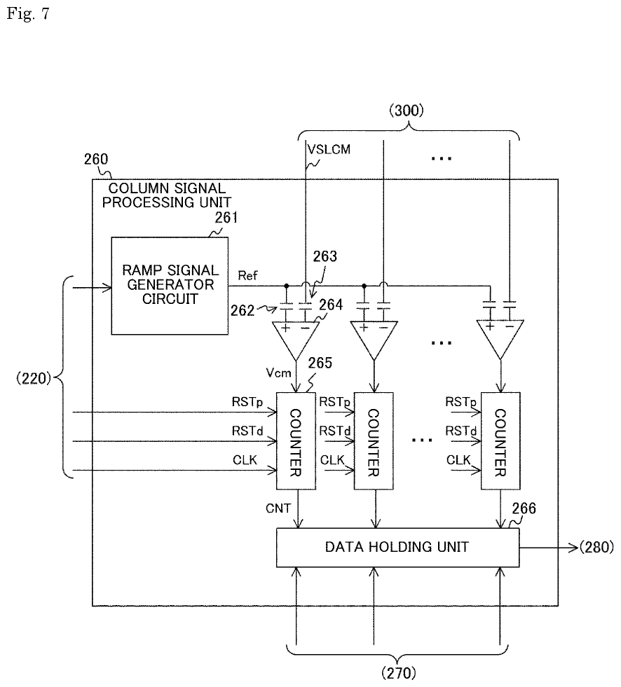

FIG. 7 is a circuit diagram illustrating a configuration example of the column signal processing unit 260 according to the first embodiment of the present technology. The column signal processing unit 260 includes a ramp signal generator circuit 261, a plurality of capacitive elements 262, a plurality of capacitive elements 263, a plurality of comparators 264, a plurality of counters 265, and a data holding unit 266. A pair of capacitive elements 262 and 263, one comparator 264, and one counter 265 are provided for each column.

The ramp signal generator circuit 261 generates a ramp signal Ref whose level gradually increases under the control of the system control unit 220.

The capacitive element 262 holds the ramp signal Ref. The capacitive element 263 holds a pixel signal from the corresponding column. These capacitive elements provide an auto-zero function.

The comparator 264 compares the ramp signal with the pixel signal on the corresponding column. This comparator 264 supplies the comparison result to the corresponding column counter 265. The comparator 264 and the counter 265 function as a single-slope analog-to-digital converter (ADC).

The counter 265 counts a count value based on the comparison result of the comparator 264. A clock signal CLK and drive signals RSTp and RSTd are input to each of the counters 265 from the system control unit 220. When the drive signal RSTp is input, the counter 265 initializes the count value. Then, the counter 265 increments the count value in synchronization with the clock signal CLK until the level of the ramp signal Ref exceeds the level of the pixel signal. Thus, the P-phase level is converted.

Then, when the drive signal RSTd is input, the counter 265 inverts the sign of the count value. After that, the counter 265 increments the count value in synchronization with the clock signal CLK until the level of the ramp signal exceeds the level of the pixel signal. Thus, a difference between the P-phase level and the D-phase level is measured. The counter 265 outputs this difference data to the data holding unit 266 as pixel data. The processing of obtaining the difference between the P-phase level and the D-phase level in this way is called the CDS processing. The capacitive elements 262 and 263 perform analog CDS processing, and the counter 265 performs digital CDS processing.

The data holding unit 266 holds pixel data of each column. The data holding unit 266 sequentially outputs the held pixel data under the control of the horizontal drive unit 270.

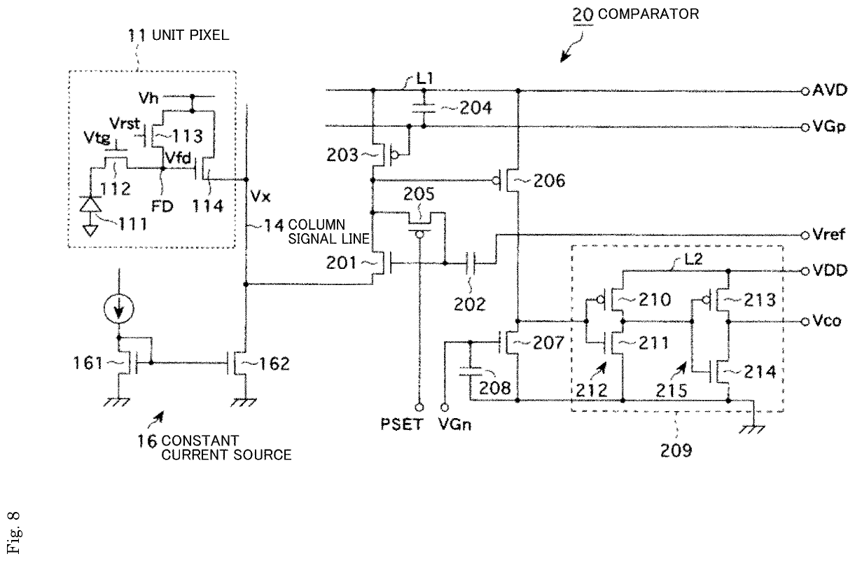

Conventional technologies will now be described with reference to FIGS. 8 to 16.

A conventional CMOS image sensor includes a photoelectric conversion element (photodiode: PD) in a unit pixel, a floating capacitance section (floating diffusion: FD) that converts electrons generated in the PD into a voltage, and an amplifier transistor that uses the FD voltage as a gate input, and the conventional CMOS image sensor commonly has a configuration that reads out a signal from a two-dimensional array of pixels with a source follower circuit using the amplifier transistor, and performs analog-to-digital conversion on the signal. Such a configuration is described, for example, in JP 2005-311487A. This circuit is illustrated in FIG. 8.

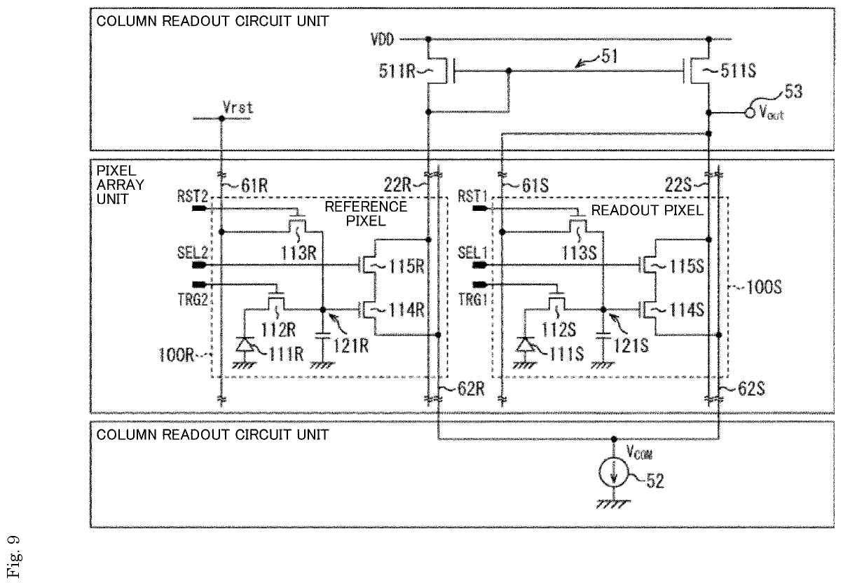

On the other hand, there is a configuration that includes the same unit pixel and additionally includes a source-grounded circuit for readout using an amplifier transistor. Such a configuration is described, for example, in JP 2018-182496A. This circuit is illustrated in FIG. 9. Hereinafter, the configuration illustrated in FIG. 8 is referred to as the source follower readout configuration, and the configuration illustrated in FIG. 9 is referred to as the differential amplification readout configuration.

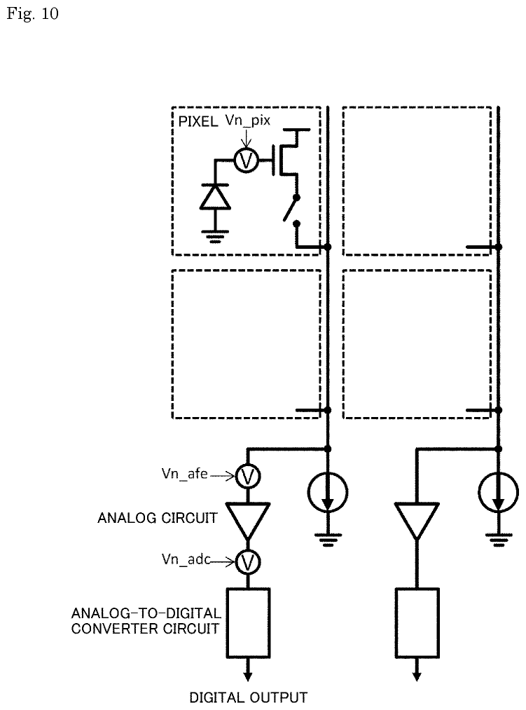

FIG. 10 is a circuit diagram illustrating locations where noise is generated in the source follower readout configuration. Electrons generated in the PD are converted into a voltage at a voltage conversion efficiency per electron (μV/e⁻) corresponding to a parasitic capacitance of the FD node. A voltage amplitude ΔVfd of the FD node corresponding to the number of signal electrons is read out from the two-dimensional array through the amplifier transistor. The signal read out at this time is mixed with noise. The major noise sources include noise Vn_pix (μVrms) generated by the amplifier transistor in the pixel, noise Vn_afe (μVrms) generated by an analog circuit (analog front end: AFE) for amplifying the voltage read out from the two-dimensional array via a signal line (VSL) and the like, and noise Vn_adc (μVrms) generated by an analog-to-digital converter circuit (ADC). Hereinafter, the noise Vn_pix is defined as input-referred voltage noise generated at the FD node, the noise Vn_afe is defined as referred voltage noise generated at the VSL, and the noise Vn_adc is defined as referred noise generated at the ADC input node.

In the source follower readout configuration, a gain Asf of a voltage amplitude ΔVvsl of the signal line (VSL) to an amplitude ΔVfd of the FD voltage is 0.8 to 1.0 times. Here, ΔVvsl=Asf×ΔVfd. Let ηfd be the conversion efficiency (μV/e⁻) of electron voltage conversion at the FD node. Accordingly, ηvsl=Asf×ηfd, where ηvsl is the conversion efficiency (μV/e⁻) of electron voltage conversion in the VSL.

Given is ΔVvsl=ηvsl×Nsig_e=ηfd×Asf×Nsig_e, where Nsig_e is the number of signal electrons. Vn_total (μVrms), in which for the sake of simplicity, the AFE does not amplify the voltage, that is, the gain is 1, and in which noise mixed with the output of the AD conversion is referred to as voltage noise generated by the VSL, is expressed by the sum (square root of mean square) of Vn_adc, Vn_afe, and Afd×Vn_pix. This indicates that the noise of Vn_total is mixed with the amplitude ΔVvsl of the VSL for the number of electrons Nsig_e. From the viewpoint of image quality, it is important how much noise is mixed with a certain number of signal electrons. Therefore, when the noise is referred to as the number of electrons at the FD node (unit: e-rms), the following equation holds.

$$\begin{matrix}[ Math . 1 ] & \\ Vn\_total \_e = \sqrt{\{ {( Vn\_adc / η vsl )}^{2} + {( Vn\_afe / η vsl )}^{2} + {( Vn\_pix / η fd )}^{2} \}} & Equation 1\end{matrix}$$

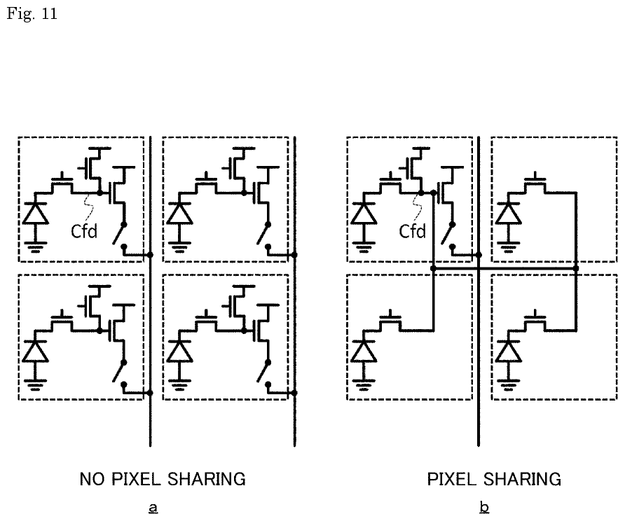

Equation 1 indicates that since ηvsl=Asf×ηfd, if Asf is increased, the effects of Vn_adc and Vn_afe can be reduced, and if ηfd is increased, the effects of Vn_adc, Vn_afe, and Vn_pix can be reduced. Asf is the voltage gain of the source follower circuit as described above, and is generally 0.8 to 1.0, and is theoretically 1.0 or less. Therefore, it is difficult to improve. ηfd is determined by a total parasitic capacitance Cfd seen from the FD node, and ηfd=e/Cfd. e is a constant of 1.602×10⁻¹⁹ coulombs in terms of the elementary amount of electrons. There is a physical limit to reducing the capacitance for noise reduction, and if a structure is adopted in which a plurality of pixels share transistors to reduce the pixel pitch as illustrated in b in FIG. 11, Cfd becomes large, making it increasingly difficult to increase ηfd. A problem with the source follower readout configuration is that since Asf is 1 at most, if ηfd cannot be increased for fine pixels, ηvsl cannot also be designed to be large, making it impossible to reduce noise.

On the other hand, with the differential amplification readout configuration, a gain Adif for the voltage amplitude ΔVvsl of the VSL is determined by a parasitic capacitance Cgd+Cfd_vsl with the VSL node, which is part of the parasitic capacitance Cfd of the FD node. Cgd is a parasitic capacitance of a transistor, and a capacitance Cfd_vsl may be intentionally added for a wire capacitance or the like in order to adjust the gain Adif. If the open-loop gain of the differential amplifier circuit in the differential amplification readout configuration is −Av, the conversion efficiency at the VSL is ηvsl=e/{Cfd/−Av+(Cgd+Cfd−vsl)}. Similarly, when the total noise with the differential amplification readout configuration is referred to as the number of electrons at the FD node, the following equation holds.

$$\begin{matrix}[ Math . 2 ] & \\ Vn\_total \_e = \sqrt{\{ {( Vn\_adc / η vsl )}^{2} + {( Vn\_afe / η vsl )}^{2} + 2 \times {( Vn\_pix / η fd )}^{2} \}} & Equation 2\end{matrix}$$

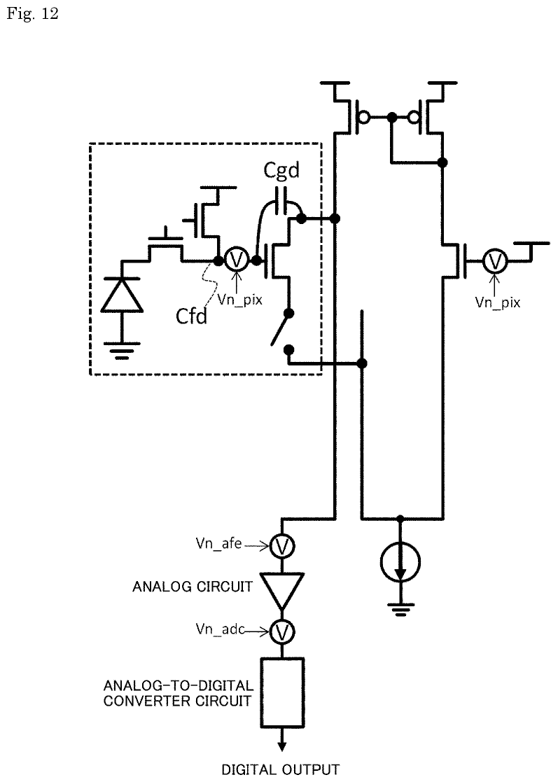

From Equation 2, it is clear that noise can be reduced by increasing ηvsl and ηfd. Now compare Equation 1 for the source follower readout configuration and Equation 2 for the differential amplification readout configuration. For Vn_adc and Vn_afe, since ηvsl in Equation 1 is Asf×ηfd, and Asf is 1.0 at maximum, ηvsl≤ηfd=e/Cfd is given. Therefore, in the situation where it is difficult to reduce Cfd, there is no way to make ηvsl higher. On the other hand, since ηvsl in Equation 2 is e/{Cfd/−Av+(Cgd+Cfd−vsl)}, and Av is generally several 10 to 100, the effect of Cfd can be suppressed, and ηvsl≈ e/Cgd. Since Cgd, which is part of Cfd, has a smaller value than Cfd and is a parasitic capacitance of the amplifier transistor as illustrated in FIG. 12, it is not a hindrance to reducing the capacitance even if the structure in which a plurality of pixels share transistors is adopted. Thus, ηvsl can be set to a larger value for the differential amplification readout configuration, which is advantageous in terms of noise.

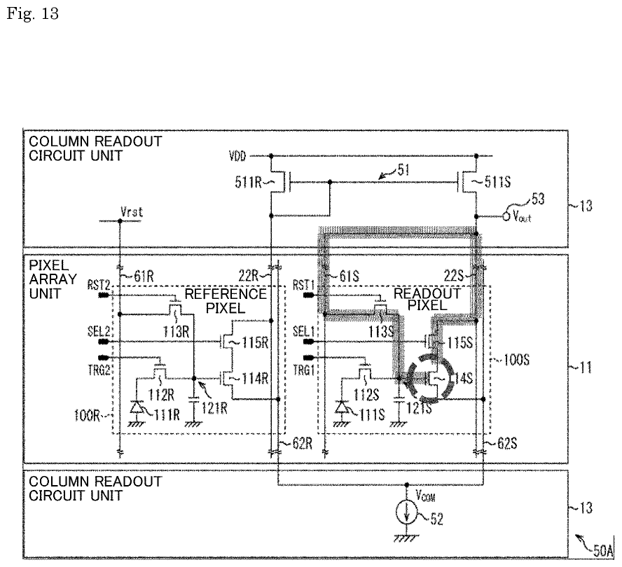

FIG. 13 is a circuit diagram illustrating an example of the state of a solid-state imaging element in a differential amplification readout configuration when initialized. As illustrated by way of example in the same figure, with the conventional differential amplification readout configuration, when the FDs of the readout and reference pixels are initialized (reset), Vᵣₛₜ is applied to the FD of the reference pixel, and the FD and VSL of the readout pixel are short-circuited through the reset transistor. At this time, the amplifier transistor of the readout pixel is diode-connected, and Vgs=Vds. It also forms a voltage follower circuit, the differential input terminals are assumed to be imaginary shorted, and the FD and VSL of the readout pixel is at the same voltage as Vᵣₛₜ. After reset release, the FD is shifted by ΔVFT due to reset feedthrough. If the readout pixel and the reference pixel have a high layout correlation, the reset feedthrough of each pixel has the same variation. A common-mode reset feedthrough, which is input to the two inputs (+/−) of the differential amplifier, is a common-mode signal, so that it is maintained at the Vᵣₛₜ voltage set at the time of reset without affecting the operating point of the VSL node. Therefore, the operating point of the amplifier transistor after reset has a relationship of Vgs′+ΔVFT≈Vds′. The reset feedthrough also shifts the Vcom node (the source of the amplifier transistor).

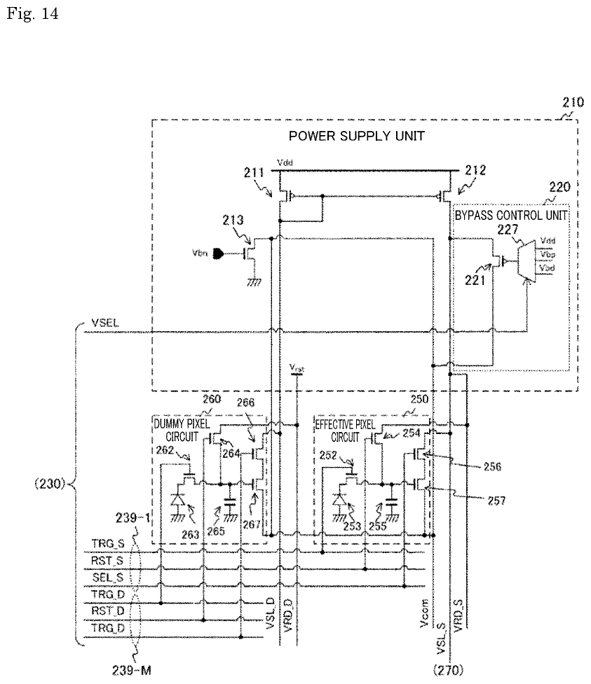

FIG. 14 is a circuit diagram of a solid-state imaging element according to a comparative example. As illustrated by way of example in the same figure, there is a technology in which when a large amount of input signal is received in differential amplification readout, an output amplitude of the VSL is clipped at a predetermined level so that an active load transistor of a pMOS current mirror section maintains the operation in the saturation region. This configuration is described in PTL 1, and this configuration is referred to as a comparative example.

In a bypass control unit (in other words, a clip circuit) of the comparative example, a current flows in a linear region or a subthreshold region from a voltage several tens of mV lower than a voltage that the VSL is clipped at a predetermined amplitude. When such a current flows, the VSL amplitude is limited without being able to ensure imaging capability because it becomes non-linear and exhibits vertical streaks due to column variations in the P-phase level and the clip circuit. To extend the dynamic range in the differential amplification readout mode, there is a way to reduce the P-phase level of the VSL in order to extend the VSL amplitude without such an influence on imaging (nonlinearity and vertical streaks). As described above, the P-phase level of the VSL is at the same voltage as Vᵣₛₜ, and when Vᵣₛₜ is reduced, the reset level of the FD is also set to a lower voltage. In order to completely transfer electrons from the PD to the FD, the FD needs to have a relatively high voltage with respect to the PD. In other words, the voltage that Vᵣₛₜ and the P-phase level of the VSL is reduced is limited by the pixel transfer characteristics.

When an even larger amount of light (a scene in which an image such as the sun is captured) is incident in the differential amplification readout, there is a case where electrons overflow from the PD to the FD beyond the barrier of the transfer transistor even though the transfer transistor is off in the P-phase. The comparator in the latter stage performs an auto-zero operation before AD conversion of the P-phase, and sets the initial state so that the two inputs (+/−) have the same voltage. When a large amount of light is incident, an overflow of electrons causes an amplitude of the VSL for P-phase conversion, so that there is no difference in voltage level from the VSL for D-phase conversion. This causes a malfunctioning black spot phenomenon in which the result of the CDS is not the full code of AD (for example, the result is a black level output) even for a large amount of incident light. In order to solve this phenomenon, according to PTL 1, the VSL is clipped at a predetermined voltage different from that of the D-phase during the P-phase period. However, in a normal imaging scene without a large amount of light, when a current in the sub-threshold region flows through the clip circuit during P-phase conversion, adverse effects on imaging occur such as vertical streaks and shading. In order to avoid this, it is necessary to reduce the P-phase clip level, but the lower limit of Vᵣₛₜ is restricted by the pixel transfer characteristics.

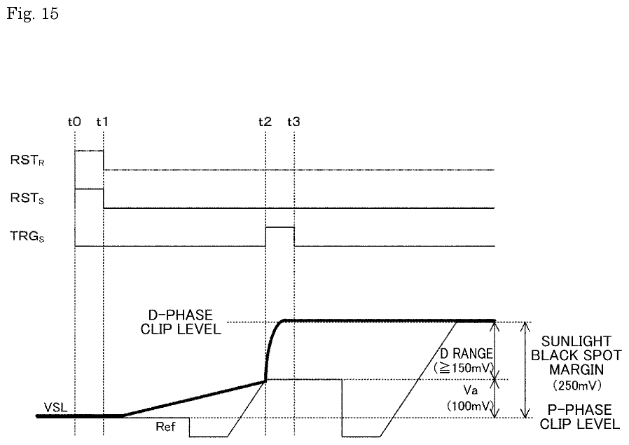

FIG. 15 is a timing chart illustrating an example of a readout operation of the CMOS image sensor according to the comparative example. A thick solid line in the same figure indicates variations in the level of the vertical signal line VSL.

Now assume that the pixels are initialized by drive signals RST_{R} and RST_{S} within a period of timing t0 to t1. Also, assume that a charge is transferred by a drive signal TRG_{S} within a period of timing t2 to timing t3.

In the comparative example, a bypass control unit (clip circuit) limits the P-phase level to the P-phase clip level or less. Here, when a large amount of light is incident, the P-phase level may rise due to insufficient limitation by the clip circuit, and accordingly, cross a ramp signal Ref at timing t2 when the P-phase conversion ends. Let Va be a difference between the ramp signal Ref at the end of the P-phase conversion and the P-phase clip level. On the other hand, assume that the D-phase level is limited to the D-phase clip level or less. In this case, the digital signal after CDS processing corresponds to a value obtained by performing AD conversion on a difference between a level obtained by adding Va to the P-phase clip level and the D-phase clip level. The value of the digital signal corresponding to this difference is set to full code.

Here, a difference between the P-phase clip level and the D-phase clip level, required to suppress the sun black spot phenomenon even when the P-phase level rises as illustrated in the same figure is referred to as a sun black spot margin. A difference between the sun black spot margin and Va corresponds to a dynamic range that can be secured to prevent the black spot phenomenon. If the sun black spot margin is 250 millivolts (mV) or higher and Va is 100 millivolts (mV), then the dynamic range is 150 millivolts (mV) or higher.

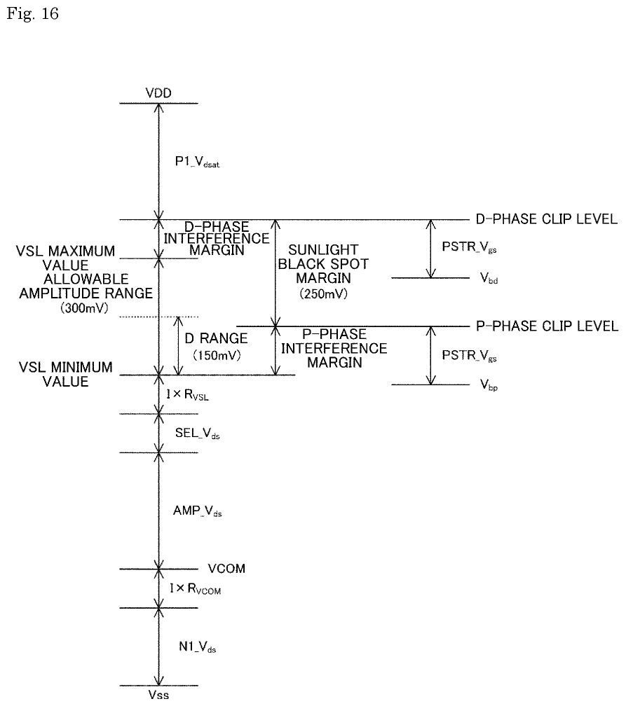

FIG. 16 illustrates an example of a level diagram in the comparative example. In the same figure, P1_V_{dsat} is a drain-source voltage of the pMOS transistor in the saturation region in the current mirror circuit.

Here, if the D-phase level is too high, a current may flow through the bypass control unit (clip circuit) and thus the linearity may be lost. A margin secured between VDD and P1_V_{dsat} such that the linearity is not lost is defined as a D-phase interference margin. A level lower than the power supply voltage VDD by P1_V_{dsat} and the D-phase interference margin is the maximum value of the vertical signal line VSL that the linearity is not lost.

On the other hand, if the P-phase level is too high, a current flows through the bypass control unit when the P-phase level is converted, resulting in increased vertical streak fixed pattern noise, so that the imaging characteristics may deteriorate. A margin secured between the minimum value of the vertical signal line VSL and the P-phase clip level such that the imaging characteristics do not deteriorate is defined as a P-phase interference margin.

I×R_{VSL} indicates an IR drop of the vertical signal line VSL. SEL_Vds indicates a drain-source voltage of the selector transistor in on-state. AMP_Vds indicates a drain-source voltage of the amplifier transistor. A level higher than the level of the common signal line VCOM by I×R_{VSL}, SEL_Vds, and AMP_Vds is the minimum value of the vertical signal line VSL.

Assume that the difference between the maximum and minimum values of the vertical signal lines VSL is 300 millivolts (mV). If the P-phase level and the D-phase level are not clipped, this 300 millivolts (mV) can be set as the dynamic range.

However, in the comparative example in which the P-phase level and the D-phase level are clipped, the dynamic range is restricted by the sun black spot margin that can be secured. For example, the maximum value of the D-phase clip level can be set to VDD-P1_V_{dsat} by a bias voltage Vbd. The minimum value of the P-phase clip level can be set to a level higher than the minimum value of the VSL by the P-phase interference margin by a bias voltage Vbp. Assume that when the P-phase clip level is set to the minimum and the D-phase clip level is set to the maximum, a sun black spot margin of 250 millivolts (mV) can be secured. In this sun black spot margin, when Va is 100 millivolts (mV), the dynamic range will be the remaining 150 millivolts (mV).

As illustrated by way of example in the same figure, in the comparative example in which the P-phase level and the D-phase level are clipped regardless of whether the voltage (amplitude) of the vertical signal line VSL exceeds the determination threshold, the dynamic range is limited by the P-phase interference margin and Va in the sun black spot margin. Although the dynamic range can be extended with a reduced P-phase clip level, it is difficult to reduce the P-phase clip level as described above with reference to FIG. 14. With a configuration in which the P-phase level and the D-phase level are not clipped, the dynamic range can be extended, but the black spot phenomenon cannot be prevented, and thus the image quality may be reduced.

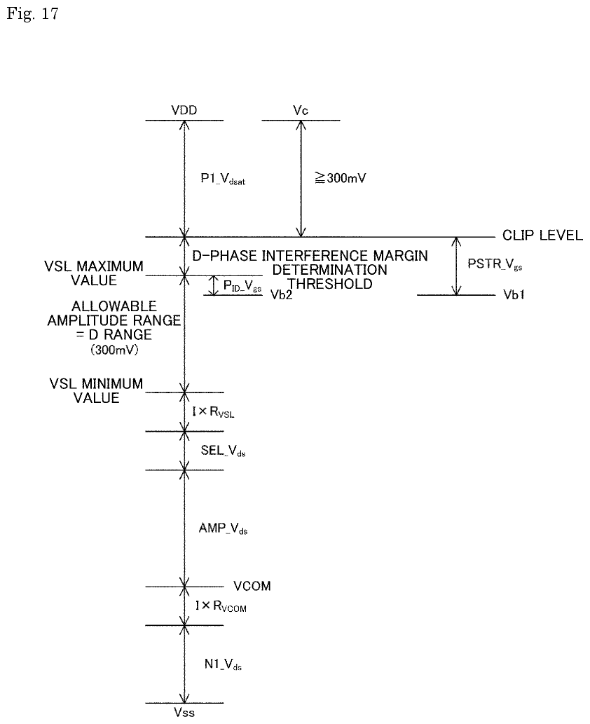

FIG. 17 illustrates an example of a level diagram in the first embodiment of the present technology. The determination threshold can be set to the maximum value of the voltage of the vertical signal line VSL by the bias voltage Vb2. The clip level can be set to VDD-P1_V_{dsat} at maximum by the bias voltage Vb1. By setting the value of the digital signal corresponding to a difference between the pull-up voltage Vc and the clip level to the full code, the difference can be used as the dynamic range. When the difference between the pull-up voltage Vc and the clip level is 300 millivolts (mV) or more, an allowable range (300 millivolts) of the amplitude of the vertical signal line VSL can be used as it is as the dynamic range.

Although the bias voltage Vb1 and the bias voltage Vb2 are set to substantially the same value in the same figure, the difference between the voltage Vc and the clip level can be increased by setting the bias voltage Vb1 to be lower than the bias voltage Vb2.

As illustrated by way of example in the same figure, with the configuration where the black spot prevention unit 340 performs clipping and pull-up when the voltage (amplitude) of the vertical signal line VSL exceeds the determination threshold, it is no longer necessary to secure the P-phase interference margin and the sun black spot margin. The budget for the clip circuit, which is defined as the above-mentioned voltage ranges required for the clip circuit of the comparative example, can be reduced as illustrated by way of example in the same figure. Accordingly, the dynamic range can be extended more than the comparative example while the sun black spot is prevented.

### [Operation Example of Solid-State Imaging Element]

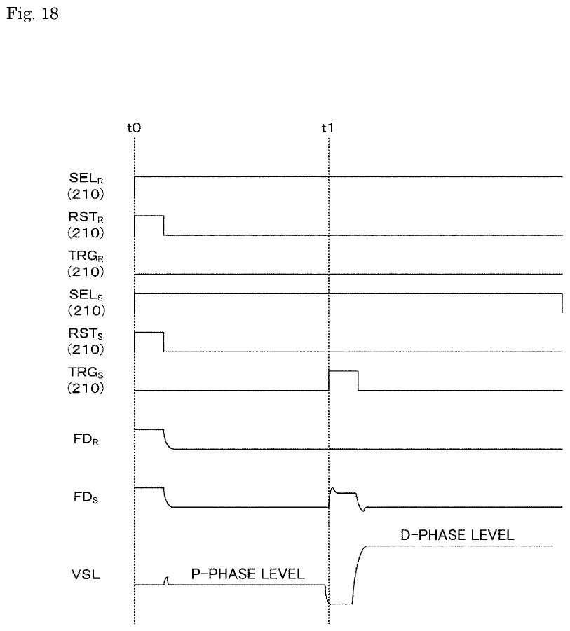

FIG. 18 is a timing chart illustrating an example of a readout operation in the differential mode in the first embodiment of the present technology.

At timing t0, the drive signals SEL_{S} and SEL_{R} for selected signal pixel and reference pixel are switched from low level to high level. As a result, a current is supplied from the tail current source 319 from the sources to the drains of the amplifier transistors 245 and 255. Then, the differential amplifier circuit using the floating diffusion region electric potential of the selected signal pixel 240 as an input voltage signal operates, so that an amplified voltage signal is output to the vertical signal line VSL. This state continues until the drive signals SEL_{S} and SEL_{R} become L level.

When high level is applied to the drive signals RST_{S} and RST_{R}, the charges accumulated in floating diffusion regions FD_{S} and FD_{R} of the signal pixel 240 and the reference pixel 250 are discharged so that their signal levels are initialized (reset). The RST_{R} of the reference pixel when not in use is always fixed at high level to extract the charge from the photodiode. The output (VSL) of the signal pixel 240 is electrically connected to the floating diffusion region FD_{S} of the signal pixel 240, which is one of the inputs of the differential amplifier circuit, through the reset transistor 243 of the signal pixel 240 and the reset bias line VRD, so that the output is negatively fed back to its FD_{S}. Since it is in a virtual ground state, the other inputs FD_{R} and FD_{S}, which are externally fixed at Vᵣₛₜ, have the same voltage. The voltage of the vertical signal line VSL is ideally Vᵣₛₜ.

When low level is applied to the drive signals RST_{S} and RST_{R} after a pulse period has elapsed from timing t0, the floating diffusion regions (FDs) of the signal pixel 240 and the reference pixel 250 are electrically disconnected from the respective reset bias line VRD so that they enter a floating state. At this time, since the floating diffusion region FD_{S} of the signal pixel and the floating diffusion region FD_{R} of the reference pixel have substantially the same structure, variations in electric potential (variations due to charge injection and clock feedthrough) at reset off are also substantially the same, and accordingly, the electric potentials of FD_{R} and FD_{S} behave almost the same. Therefore, the output of the differential amplifier circuit is almost unchanged from Vᵣₛₜ at reset on. This state is a reset (initial) state in differential amplification readout, and this output level is a reset (initial) level. This is because the differential amplifier circuit does not amplify the common-mode signal components of both inputs. The column signal processing unit 260 performs AD conversion on this reset level as the P-phase level.

Next, when the drive signal TRG_{S} of the signal pixel 240 is applied in a pulse form at timing t1, the charge accumulated in the photodiode of the signal pixel 240 is transferred to the floating diffusion region FD_{S} by the transfer transistor 242. The electric potential of the floating diffusion region of the signal pixel 240 is modulated by the transferred charge. When this is input as a voltage signal to the gate of the amplifier transistor 245 of the signal pixel 240, a voltage signal corresponding to the accumulated amount of charge is output to the vertical signal line VSL. The column signal processing unit 260 performs AD conversion on this signal level as the D-phase level. The column signal processing unit 260 performs the CDS processing by subtracting the P-phase level from the D-phase level, and reads out pixel signals from which fixed pattern noise and offset have been removed.

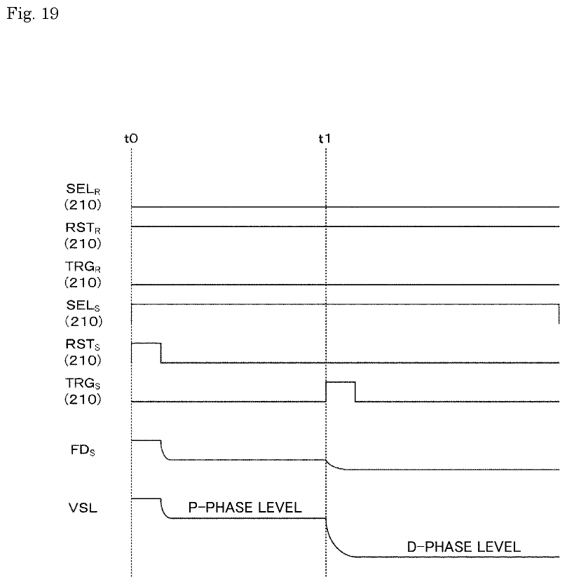

FIG. 19 is a timing chart illustrating an example of a readout operation in the SF mode in the first embodiment of the present technology.

At timing t0, the drive signal SEL_{S} of the selected signal pixel 240 is switched from low level to high level. As a result, a current is supplied from the drain (VDD) of the amplifier transistor 245 to the source, and the source follower circuit using the electric potential of the floating diffusion region FD_{S} of the selected signal pixel 240 as an input voltage signal operates, so that a voltage signal is output to the vertical signal line VSL. This state continues until the drive signal SEL_{S} becomes low level.

When a drive signal RST_{S} with high level is applied, the charge accumulated in the floating diffusion region of the signal pixel 240 is discharged so that the level of the pixel signal is initialized (reset).

When a drive signal RST_{S} with low level is applied after a pulse period has elapsed from timing t0, the floating diffusion regions of the signal pixel 240 and the reference pixel 250 are electrically disconnected from the respective reset bias line VRD so that they enter a floating state. The column signal processing unit 260 performs AD conversion on this reset level as the P-phase level.

Next, when the drive signal TRG_{S} of the signal pixel 240 is applied in a pulse form at timing t1, the charge accumulated in the photodiode of the signal pixel 240 is transferred to the floating diffusion region FD_{S} by the transfer transistor 242. The electric potential of the floating diffusion region of the signal pixel 240 is modulated by the transferred charge, and when this is input as a voltage signal to the gate of the amplifier transistor 245 of the signal pixel 240, a voltage signal corresponding to the accumulated amount of charge is output from the vertical signal line VSL on the signal side. The column signal processing unit 260 performs AD conversion on this signal level as the D-phase level. The column signal processing unit 260 performs the CDS processing by subtracting the P-phase level from the D-phase level, and reads out pixel signals from which fixed pattern noise and offset have been removed.

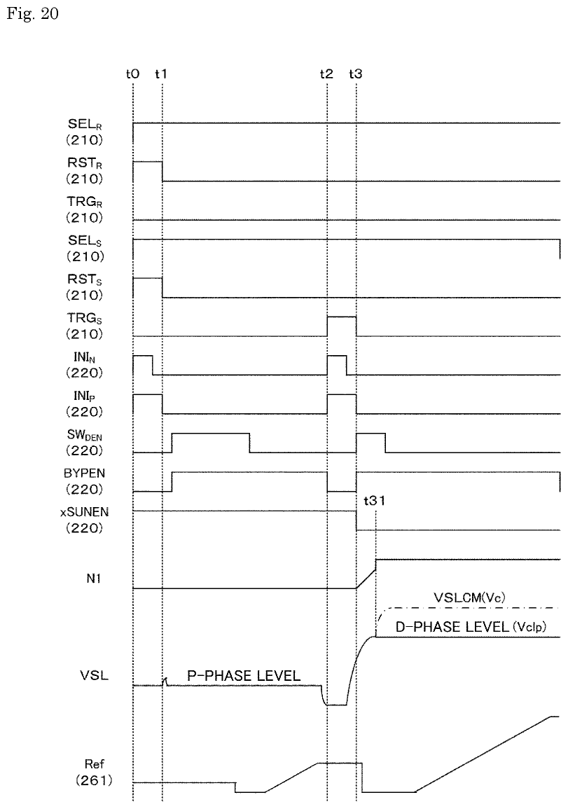

FIG. 20 is a timing chart illustrating an example of a readout operation in the differential mode when a large amount of light that does not cause overflow is incident in the first embodiment of the present technology.

At timing t0 for pixel reset, the system control unit 220 sets the control signal INI_{N} to high level to reset the node N1 to 0 volts (V). After the control signal INI_{N} becomes low level, the system control unit 220 sets the control signal INI_{P} to low level at timing t1 so that a through current does not flow.

The system control unit 220 sets the control signal SW_{DEN} to high level after timing t1, and sets it to low level before AD conversion of the P-phase level. After the charge is transferred by the drive signal TRG_{S} at timing t2, the system control unit 220 sets the control signal SW_{DEN} to high level, and sets it to low level before AD conversion of the D-phase level. The system control unit 220 turns off the amplitude detection unit 320 so that the pull-up circuit 360 does not operate during AD conversion.

When an amplitude of the vertical signal line VSL occurs after timing t3 and exceeds the determination threshold controlled by the bias voltage Vb2, a current flows from the vertical signal line VSL to the node N1 to charge the capacitive element 324. When the voltage of the node N1 rises and exceeds the logic threshold of the NAND gate 334, the node N2 is inverted from high level to low level, and the node N1 is inverted to high level at timing t31.

As described above, even if the vertical signal line VSL varies due to noise or the like, the diode-connected pMOS transistor 323 prevents the current of the node N1 from flowing backward and thus flipping back to low level again. In addition, even in the case where the level of the vertical signal line VSL is close to the determination threshold and the charging of the node N1 is slow, the positive feedback logic provides the effect of increasing the inversion speed of the node N1.

Since the node N1 is at low level (that is, the voltage of the vertical signal line VSL exceeds the determination threshold) and the control signal BYPEN for controlling the clip period is at high level, the function of the clip unit 350 is enabled. As a result, the vertical signal line VSL is clipped at a clip level Vclp controlled by the bias voltage Vb1, and any further amplitude does not occur.

After timing t3, the system control unit 220 sets the control signal xSUNEN to low level (enabled), and when the node N1 is at low level, the switch (pMOS transistor 362) that connects the vertical signal line VSL and the comparator-side vertical signal line VSLCM is in off-state. The comparator-side vertical signal line VSLCM is pulled up to the predetermined voltage Vc. Vc is a voltage higher than Vclp, and Vc-Vclp is equal to or greater than the full code voltage of the ADC.

The clip level Vclp is a level at which the tail current source 319 can maintain the saturation region operation. The system control unit 220 sets the control signal INI_{N} to high level in a period between timings t2 and t3 for transfer to reset the node N1. Although this drive is not always necessary, in case where the node N1 is charged with a leak current at high temperature or the like, the node N1 is reset, and the amplitude of the vertical signal line VSL is detected again in the D-phase.

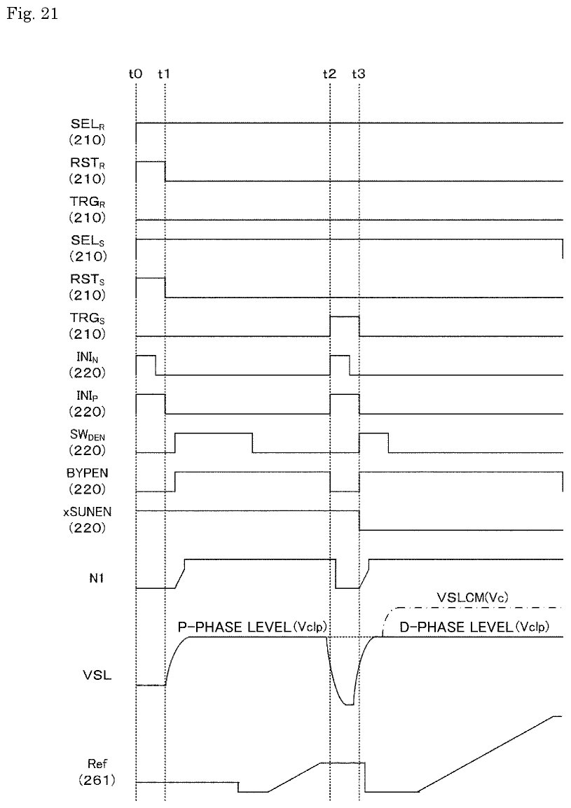

FIG. 21 is a timing chart illustrating an example of a readout operation when overflow occurs in the first embodiment of the present technology.

After timing t1 for pixel reset, charge overflow occurs in the FD, and an amplitude of the voltage of the vertical signal line VSL occurs. The amplitude of the vertical signal line VSL is detected, the node N1 is inverted to high level, the clip unit 350 operates to clip the vertical signal line VSL at the clip level Vclp.

In a period of timings t2 to t3 for transfer, the system control unit 220 sets the control signal BYPEN to low level to disable the clip function. Although the control signal INI_{N} becomes high level and accordingly, the node N1 is reset to 0 V again, the amplitude is detected again and the control signal INI_{N} is inverted to high level after timing t3. The comparator-side vertical signal line VSLCM is connected to the voltage Vc. The comparator-side vertical signal line VSLCM for P-phase conversion is set to the auto-zero level of the comparator 264 at the clip level Vclp. On the other hand, since the comparator-side vertical signal line VSLCM for D-phase conversion is at the level of Vc, the result of the CDS is always the full code of AD.

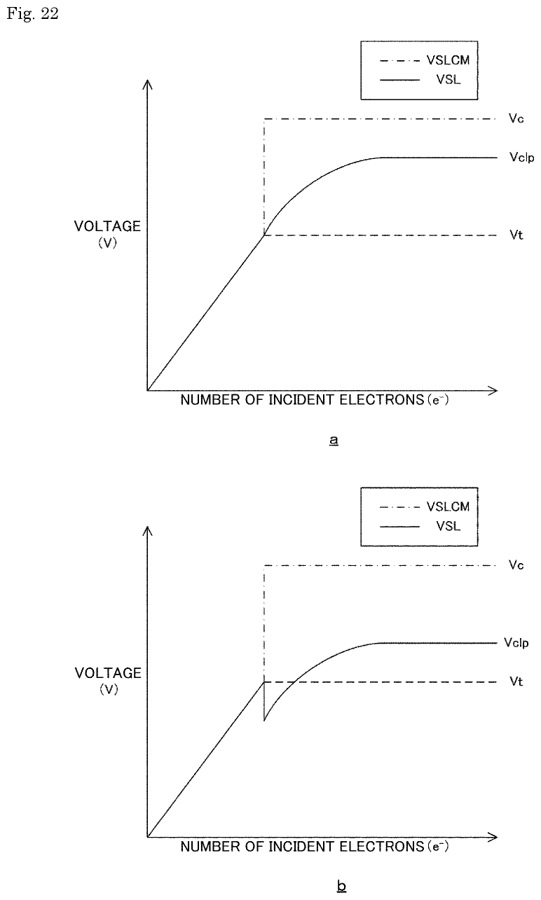

FIG. 22 illustrates an example of a relationship between the voltage and the number of incident electrons in the first embodiment of the present technology. In the same figure, a is a diagram illustrating an example of a relationship between the voltage and the number of incident electrons when the bias voltage Vb1 and the bias voltage Vb2 are set substantially the same. In the same figure, a is a diagram illustrating an example of a relationship between the voltage and the number of incident electrons when the bias voltage Vb1 is lower than the bias voltage Vb2. In the same figure, the vertical axis indicates voltage, and the horizontal axis indicates the number of electrons incident on the photodiode. A solid curve indicates the voltage characteristics of the vertical signal line VSL, and a constant chain line indicates the voltage characteristics of the comparator-side vertical signal line VSLCM. Assume that the pMOS transistor 351 to which the bias voltage Vb1 is applied and the pMOS transistor 322 to which the bias voltage Vb2 is applied have approximately the same gate width/gate length ratio.

As illustrated by way of example in a of the same figure, for Vb1=Vb2, the comparator-side vertical signal line VSLCM is pulled up to Vc when a determination threshold Vt controlled by the bias voltage Vb2 is exceeded. The voltage of the vertical signal line VSL can have an amplitude up to the clip level Vclp controlled by the bias voltage Vb1.

As illustrated by way of example in b of the same figure, for Vb1<Vb2, the bias voltage Vb1 is reduced as compared to a of the same figure, and accordingly, a potential difference of Vc−Vclp can be increased. Since the clip level Vclp is reduced, a margin is created for the drain-source voltage Vds required for the tail current source 319 to operate in the saturation region. A similar effect can be obtained by setting the gate width/gate length ratio of the pMOS transistor 322 corresponding to Vb2 to be smaller than the gate width/gate length ratio of the pMOS transistor 351 corresponding to Vb1.

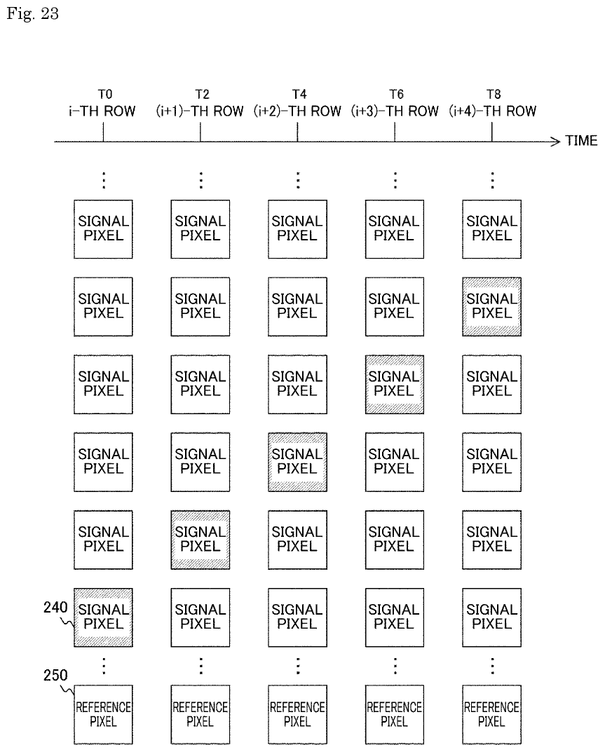

FIG. 23 illustrates an example of a readout order of signal pixels according to the first embodiment of the present technology. The differential amplification readout is, for example, pixel access as illustrated in the same figure. Focusing on a certain column, the i-th row is read out at timing T0, and the (i+1)-th row is read out at timing T1. After that, readout rows are selected in order.

The signal pixels 240 are sequentially read out by the rolling shutter operation, while the reference pixels 250 are fixedly selected in one row. It is desirable that the reference pixels 250 are physically shielded from light.

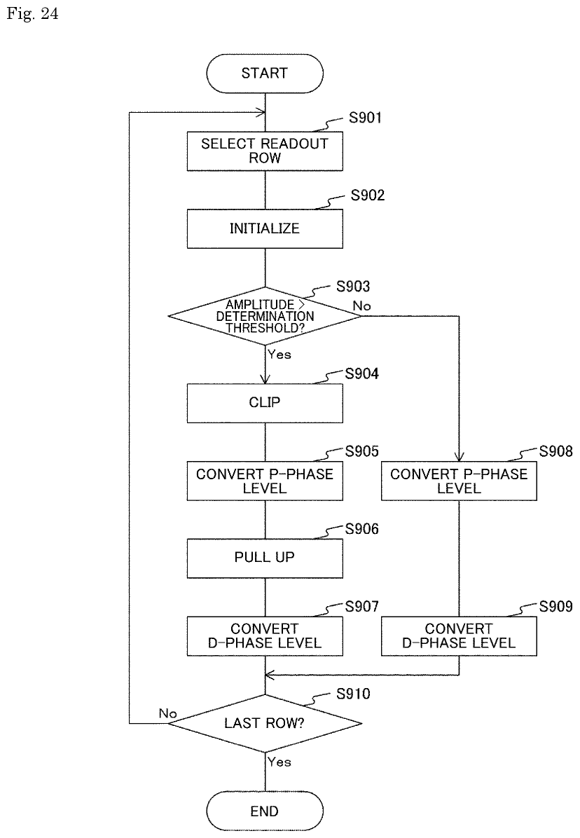

FIG. 24 is a flowchart illustrating an example of the operation of the CMOS image sensor 200 according to the first embodiment of the present technology. This operation is started, for example, when the differential mode is set.

The vertical drive unit 210 selects a readout row after exposure (step S901) and initializes that row (step S902). The column readout circuit unit 300 determines whether or not the amplitude of the vertical signal line exceeds the determination threshold (step S903).

When the amplitude exceeds the determination threshold (step S903: Yes), the column readout circuit unit 300 clips the voltage of the vertical signal line VSL (step S904), and the column signal processing unit 260 converts the P-phase level (step S905). The column readout circuit unit 300 pulls up the voltage of the comparator-side vertical signal line VSLCM (step S906), and the column signal processing unit 260 converts the D-phase level (step S907).

On the other hand, when the amplitude is equal to or less than the determination threshold (step S903: No), the column signal processing unit 260 converts the P-phase level (step S909) and converts the D-phase level (step S910).

After step S907 or S909, the vertical drive unit 210 determines whether or not the readout row is the last row (step S910). If the readout row is not the last line (step S910: No), the CMOS image sensor 200 repeats step S901 and subsequent steps. On the other hand, if the readout row is not the last line (step S910: Yes), the CMOS image sensor 200 ends the operation for imaging.

The timing charts of FIGS. 18, 20 and 21 indicate the operations of steps S904 to S909 of FIG. 24.

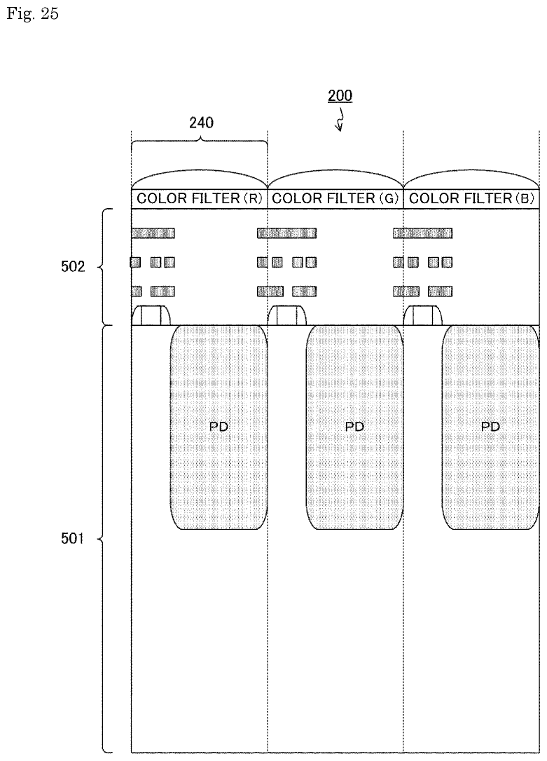

FIG. 25 is an example of a cross-sectional view of a front-illuminated CMOS image sensor 200 according to the first embodiment of the present technology. A wiring layer 502 is arranged below microlenses, and a photoelectric conversion layer 501 is provided below it. In the wiring layer 502, transistors and signal lines are provided. In the photoelectric conversion layer 501, photodiodes are arranged.

As illustrated by way of example in the same figure, in the CMOS image sensor 200 in which the wiring layer 502 is arranged between the microlenses and the photoelectric conversion layer 501, the surface on which the circuit is arranged is illuminated with light. Such a solid-state imaging device is called a front-illuminated solid-state imaging device.

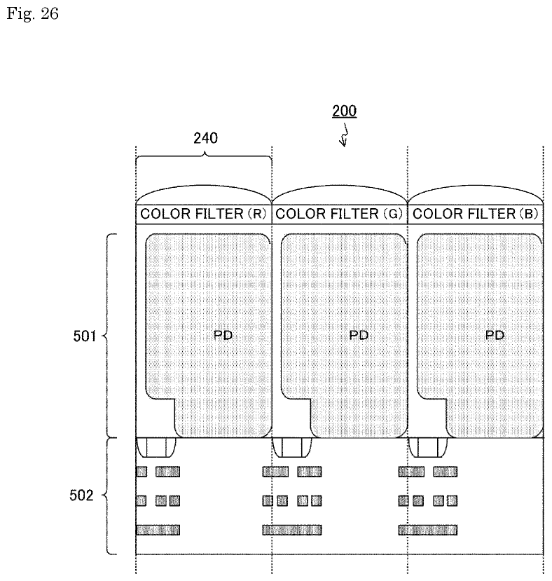

As illustrated in FIG. 26, a back-illuminated structure may be used. A photoelectric conversion layer 501 is arranged below microlenses, and a wiring layer 502 is provided below it.

As illustrated by way of example in the same figure, in the CMOS image sensor 200 in which the photoelectric conversion layer 501 is arranged between the microlenses and the wiring layer 502, the back surface facing the front surface is illuminated with light. Such a solid-state imaging device is called a back-illuminated solid-state imaging device. In the back-illuminated type, the light is not blocked by part of the wiring layer, so that the sensitivity can be higher than that of the front-illuminated type.

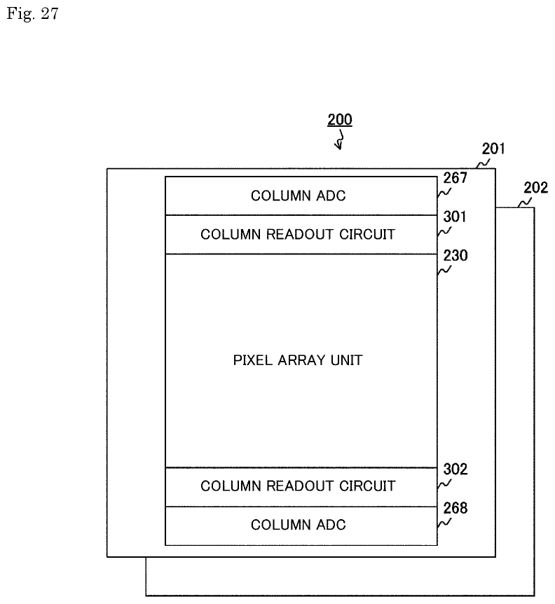

In a case where a back-illuminated structure is used, a laminated structure can be used in which a pixel substrate 201 and a support substrate 202 are laminated, as illustrated by way of example in FIG. 27. A pixel array unit 230, column readout circuits 301 and 302, and column ADCs 267 and 268 are arranged on the pixel substrate 201. Half of the circuits in the column readout circuit unit 300 are arranged in the column readout circuit 301 and the rest are arranged in the column readout circuit 302. Half of the ADCs in the column signal processing unit 260 are arranged in the column ADC 267 and the rest are arranged in the column ADC 268.

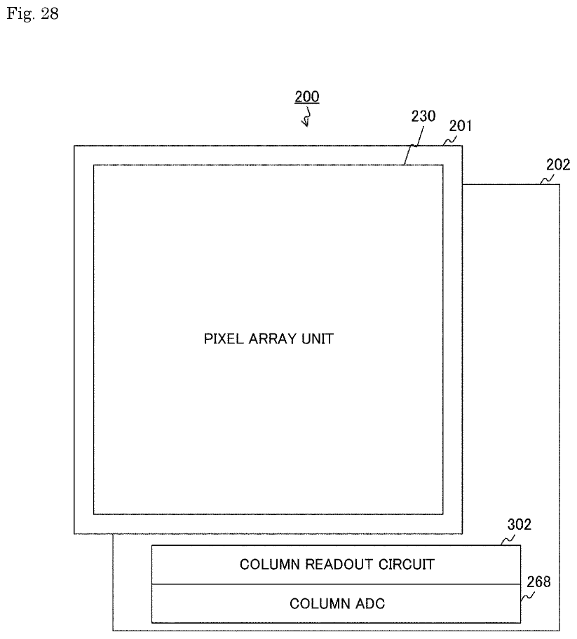

In a case where a laminated structure is used, only the pixel array unit 230 can be arranged on the pixel substrate 201, and the subsequent circuit can be arranged on the support substrate 202, as illustrated by way of example in FIG. 28.

As described above, according to the first embodiment of the present technology, when the output voltage of the vertical signal line exceeds the determination threshold, the black spot prevention unit 340 performs clipping and pull-up, so that the dynamic range can be extended while the black spot phenomenon is prevented. Accordingly, the image quality of image data can be improved.

### 2. Second Embodiment

In the above-described first embodiment, when the output voltage of the vertical signal line exceeds the determination threshold, the black spot prevention unit 340 pulls up the voltage for D-phase conversion. However, a counter 265 may be controlled instead of the pull-up. A CMOS image sensor 200 according to a second embodiment differs from that according to the first embodiment in that the counter 265 is controlled for D-phase conversion.

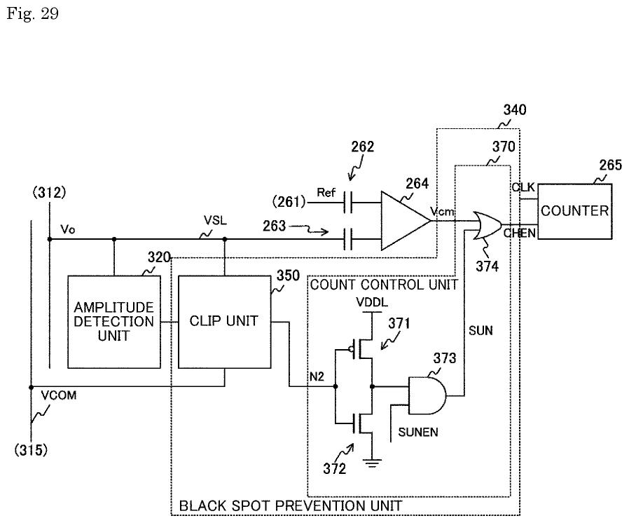

FIG. 29 is a circuit diagram illustrating a configuration example of an amplitude detection unit 320 and a black spot prevention unit 340 according to a second embodiment of the present technology. The black spot prevention unit 340 of the second embodiment differs from that of the first embodiment in that it includes a count control unit 370 instead of the pull-up circuit 360.

The count control unit 370 controls a digital signal corresponding to the D-phase level to the full code. This count control unit 370 includes a pMOS transistor 371, an nMOS transistor 372, an AND (logical AND) gate 373 and an OR (logical OR) gate 374.

The pMOS transistor 371 and the nMOS transistor 372 are connected in series between a voltage VDDL lower than the power supply voltage VDD and a ground node. The gates of the pMOS transistor 371 and nMOS transistor 372 are connected to a node N2. These pMOS transistor 371 and nMOS transistor 372 function as an inverter that inverts the level of the node N2.

The AND gate 373 supplies as a control signal SUN a logical AND of a control signal SUNEN from the system control unit 220 and a connection node between the pMOS transistor 371 and the nMOS transistor 372 to the OR gate 374. The control signal SUNEN is set to high level to enable the count control unit 370, and is set to low level to disable the count control unit 370.

The OR gate 374 supplies as a control signal CHEN a logical OR of a comparison result Vcm from a comparator 264 and the control signal SUN from the AND gate 373 to the counter 265, instead of the comparison result Vcm.

With the above-described circuit configuration, when the amplitude exceeds the determination threshold and accordingly, the node N2 is inverted to low level, the output of the inverter (the pMOS transistor 371 and the nMOS transistor 372) is inverted to high level. When the output of the inverter is inverted to high level, the control signal SUN becomes high level if the control signal SUNEN is at high level, and a control signal CHEN with high level is supplied to the counter 265 regardless of the comparison result Vcm.

The counter 265 counts the count value in synchronization with a clock signal CLK over a period in which the control signal CHEN is at high level.

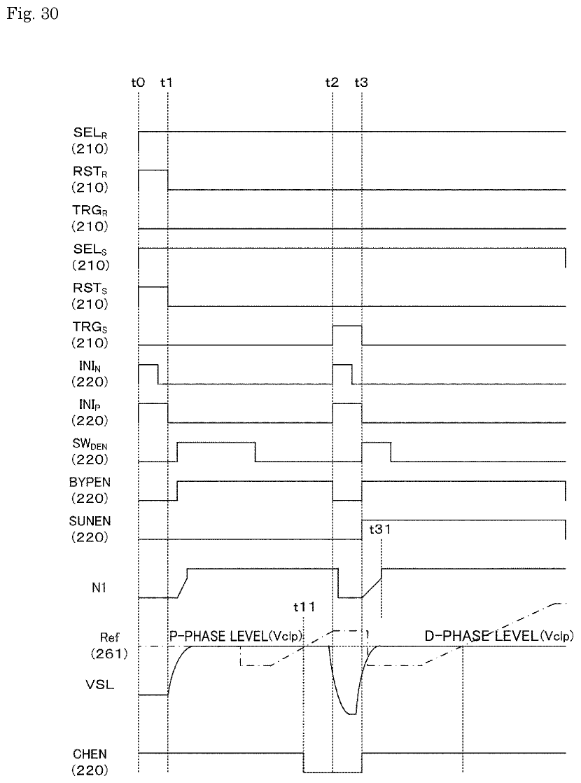

FIG. 30 is a timing chart illustrating an example of a readout operation in the differential mode in the second embodiment of the present technology. Now assume that a large amount of light is incident and accordingly, charge overflow to the FD occurs. In addition, in the same figure, for convenience of explanation, a vertical signal line VSL and a ramp signal Ref have the same voltage immediately after the auto zero. Actually, two inputs of the comparator 264 in which DC is cut by capacitive elements 262 and 263 on the VSL side and the Ref side have the same voltage.

In the single-slope ADC (the comparator 264 and the counter 265), the counter 265 starts counting at the beginning of the slope of the ramp signal Ref starts. Then, when the ramp signal Ref and the VSL cross each other near a voltage set by auto-zero, the comparison result Vcm is inverted and the count operation is stopped.

Since the control signal SUNEN is at high level during the D-phase period after timing T3 and the node N2 indicating the result of detecting the amplitude of the VSL is at low level, the control signal SUN is at high level. Since the control signal SUN is high level, the control signal CNEN is at high level regardless of the state of the comparison result Vcm from the comparator 264 in the conversion of the D-phase level. Thus, the counter 265 continues the counting until the slope of the ramp signal Ref for D-phase conversion ends. Since the D-phase is always counted full, a difference between a digital signal corresponding to the D-phase level and a digital signal corresponding to the P-phase level (that is, the CDS result) can always be a full code. As a result, the black spot phenomenon can be prevented.

As described above, according to the second embodiment of the present technology, when the output voltage of the vertical signal line exceeds the determination threshold, the count control unit 370 controls the digital signal to full code. This eliminates the pull-up circuit 360, and also eliminates the supply of the relatively high voltage Vc.

### 3. Third Embodiment

In the above-described first embodiment, the clip unit 350 and the pull-up circuit 360 are arranged for each column, but the larger the number of columns, the larger the circuit scale. A CMOS image sensor 200 according to a third embodiment differs from that according to the second embodiment in that the clip unit 350 is eliminated.

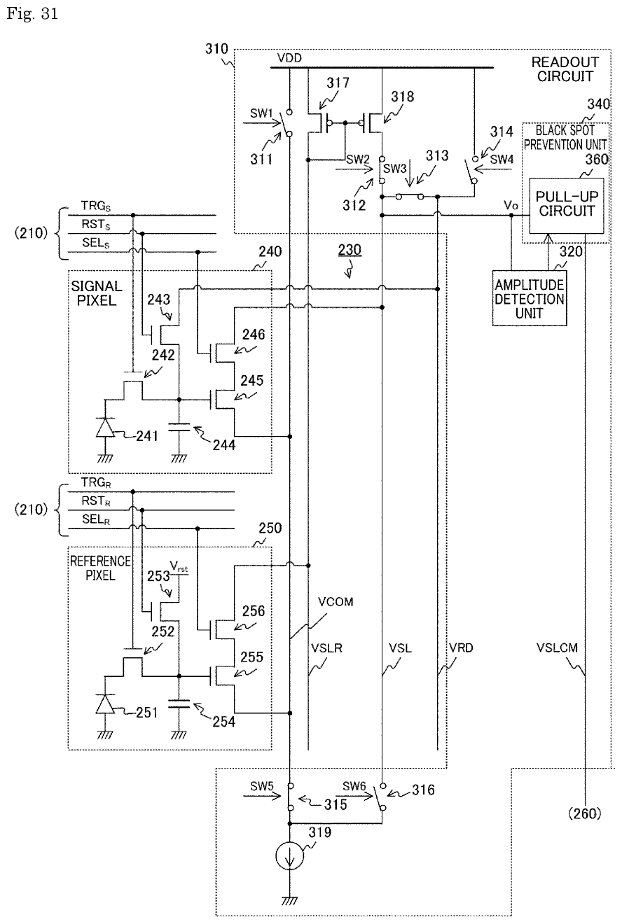

FIG. 31 is a circuit diagram illustrating a configuration example of a pixel array unit 230 and a readout circuit 310 according to the third embodiment of the present technology. The readout circuit 310 of the third embodiment differs from that of the first embodiment in that the clip unit 350 is eliminated and only the pull-up circuit 360 is arranged in the black spot prevention unit 340. In the third embodiment, the amplitude detection unit 320 is set to be enabled only for the conversion of the D-phase level.

Even in the configuration illustrated in the same figure, since it is only necessary to detect the amplitude of the vertical signal line VSL for D-phase level conversion, the voltage budget that occupies the VSL can be reduced as compared to the comparative example. This is advantageous to extend the dynamic range.

The second embodiment can be applied to the third embodiment.

As described above, according to the third embodiment of the present technology, the clip unit 350 is not arranged, so that the circuit scale can be reduced accordingly.

### 4. Fourth Embodiment

In the above-described first embodiment, the clip unit 350 and the pull-up circuit 360 are arranged for each column, but the larger the number of columns, the larger the circuit scale. A CMOS image sensor 200 according to a fourth embodiment differs from that according to the first embodiment in that the pull-up circuit 360 is eliminated.

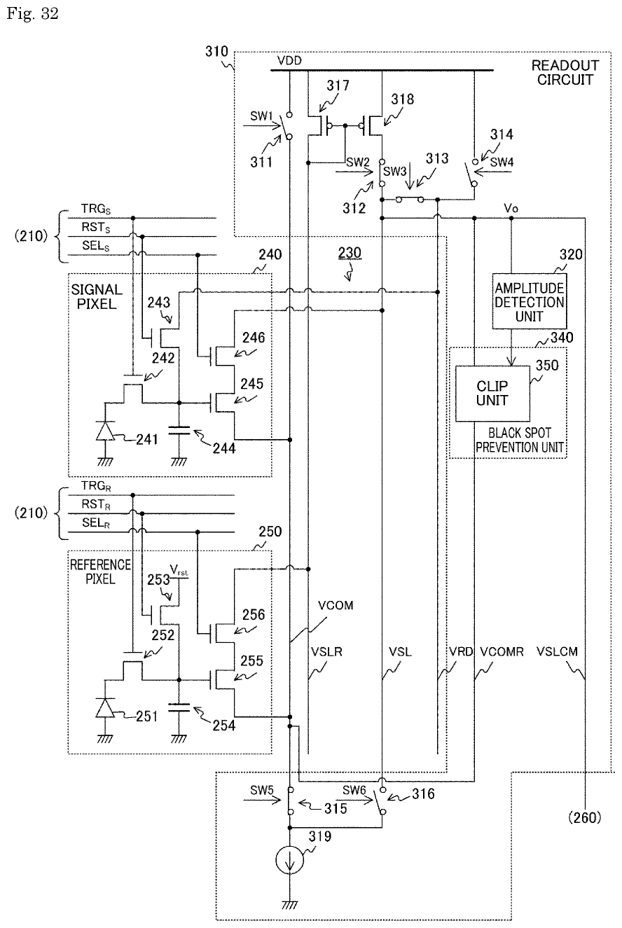

FIG. 32 is a circuit diagram illustrating a configuration example of a pixel array unit 230 and a readout circuit 310 according to the fourth embodiment of the present technology. The readout circuit 310 of the fourth embodiment differs from that of the first embodiment in that the pull-up circuit 360 is eliminated and only the clip unit 350 is arranged in the black spot prevention unit 340.

With the configuration of the same figure as well, the VSL budget for the clip unit 350 can be reduced by reducing the potential difference between the determination threshold and the clip level, which is advantageous to extend the dynamic range over the comparative example.

As described above, according to the fourth embodiment of the present technology, the pull-up circuit 360 is not arranged, so that the circuit scale can be reduced accordingly.

### 5. Fifth Embodiment

In the above-described first embodiment, the clip unit 350 performing the clipping when the output voltage of the vertical signal line exceeds the determination threshold. However, the system control unit 220 may control the clip unit 350 independently of the amplitude detection unit 320. A CMOS image sensor 200 according to a fifth embodiment differs from that according to the first embodiment in that the clip unit 350 performing the clipping when enabled by the control signal BYPEN.

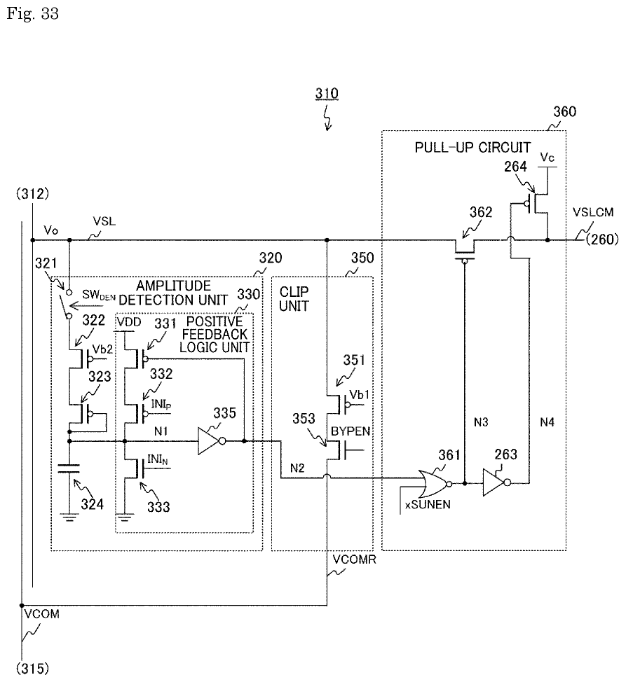

FIG. 33 is a circuit diagram illustrating a configuration example of an amplitude detection unit 320, a clip unit 350, and a pull-up circuit 360 according to the fifth embodiment of the present technology. The clip unit 350 of the fifth embodiment differs from that of the first embodiment in that it includes an nMOS transistor 353 instead of the pMOS transistor 352.

The nMOS transistor 353 is inserted between the pMOS transistor 351 and the comparator-side vertical signal line VSLCM, and the control signal BYPEN is input to the gate of the nMOS transistor 353. The control signal BYPEN is set to high level to enable the clip unit 350, and the control signal BYPEN is set to low level to disable the clip unit 350.

The system control unit 220 enables the clip unit 350 by the control signal BYPEN for the conversion of the P-phase level. According to the configuration of the same figure, the voltage budget for the pull-up circuit 360 can be reduced, which is advantageous over the comparative example.

Each of the second to fourth embodiments can be applied to the fifth embodiment.

As described above, according to the fifth embodiment of the present technology, the clip unit 350 performs the clipping when enabled, so that the clip unit 350 can be controlled independently of the amplitude detection unit 320.

### 6. Sixth Embodiment

In the above-described first embodiment, the comparator-side vertical signal line VSLCM is wired for each column in the pixel array unit 230, but the larger the number of columns, the larger the number of wiring lines in the pixel array unit 230. A CMOS image sensor 200 according to a sixth embodiment differs from that according to the first embodiment in that the number of wiring lines in the pixel array unit 230 is reduced.

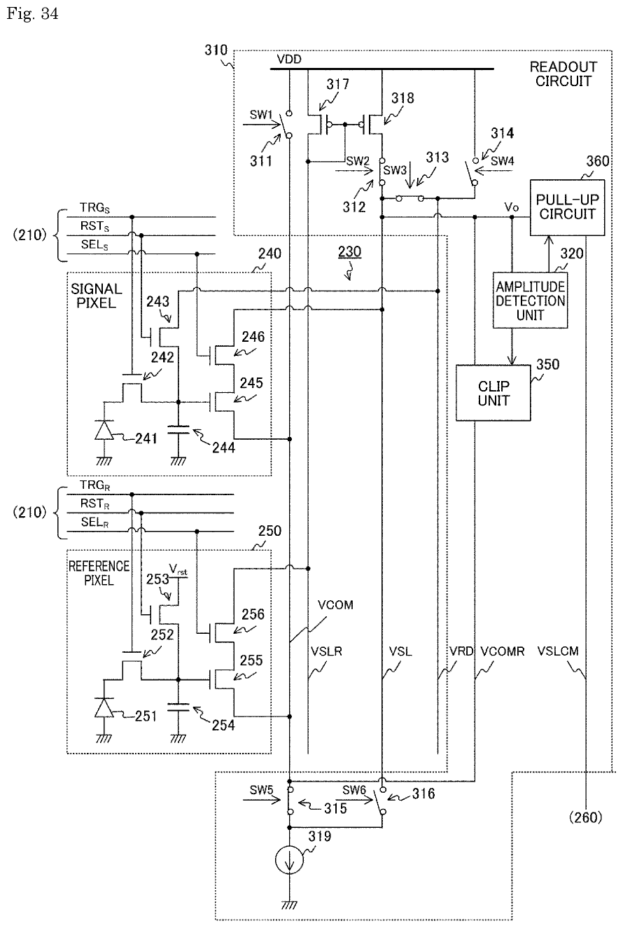

FIG. 34 is a circuit diagram illustrating a configuration example of a pixel array unit 230 and a readout circuit 310 according to the sixth embodiment of the present technology. The pixel array unit 230 of the sixth embodiment differs from that of the first embodiment in that the comparator-side vertical signal line VSLCM is not wired. The clip unit 350 of the sixth embodiment is connected to a node in the vicinity of the switch 315 in the readout circuit 310 via the comparator-side vertical signal line VSLCM.

Each of the second to fifth embodiments can be applied to the sixth embodiment.

As described above, according to the sixth embodiment of the present technology, the comparator-side vertical signal line VSLCM is not wired in the pixel array unit 230, so that the number of wiring lines in the pixel array unit 230 can be reduced.

### 7. Seventh Embodiment

In the above-described first embodiment, the positive feedback logic unit 330 increases the inversion speed of the node N1. However, if the inversion speed of the node N1 is sufficiently high, the positive feedback logic unit 330 may be eliminated. A CMOS image sensor 200 according to a seventh embodiment differs from that according to the first embodiment in that the positive feedback logic unit 330 is eliminated.

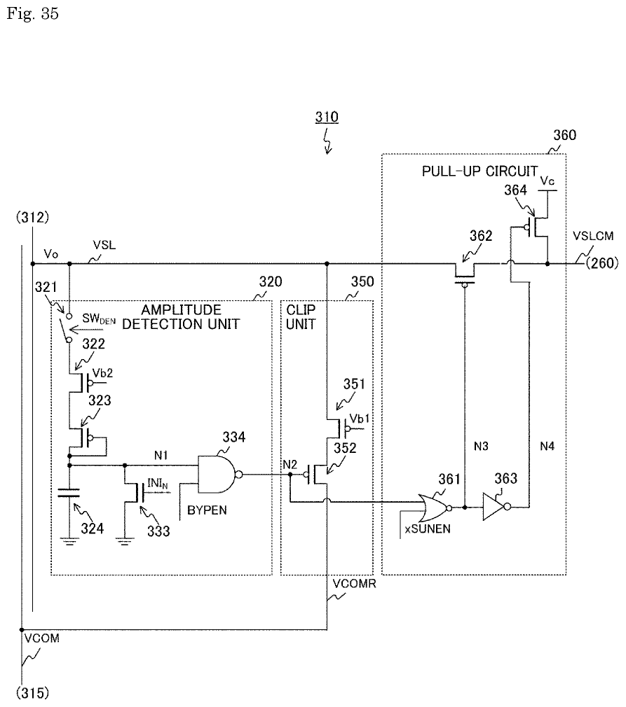

FIG. 35 is a circuit diagram illustrating a configuration example of an amplitude detection unit 320, a clip unit 350, and a pull-up circuit 360 according to the seventh embodiment of the present technology. The amplitude detection unit 320 of the seventh embodiment differs from the first embodiment in that an nMOS transistor 333 and a NAND gate 334 are arranged instead of the positive feedback logic unit 330. The NAND gate 334 is an example of a logic gate described in the claims.

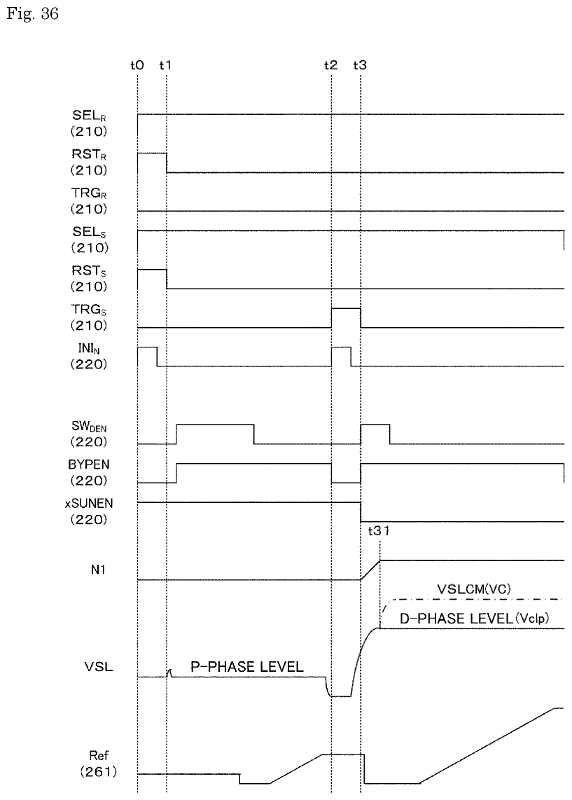

FIG. 36 is a timing chart illustrating an example of a readout operation in the differential mode in the seventh embodiment of the present technology. As illustrated by way of example in the same figure, when the node N1 becomes high level at timing t31, the node N1 is not charged to the power supply voltage VDD.

Each of the second to sixth embodiments can be applied to the seventh embodiment.

As described above, according to the seventh embodiment of the present technology, the positive feedback logic unit 330 is not arranged, so that the circuit scale can be reduced.

### 8. Eighth Embodiment

In the above-described first embodiment, the floating diffusion region (FD) is arranged for each pixel. However, an FD may be shared by a plurality of pixels. A CMOS image sensor 200 according to an eighth embodiment differs from that according to the first embodiment in that an FD is shared by a plurality of pixels.

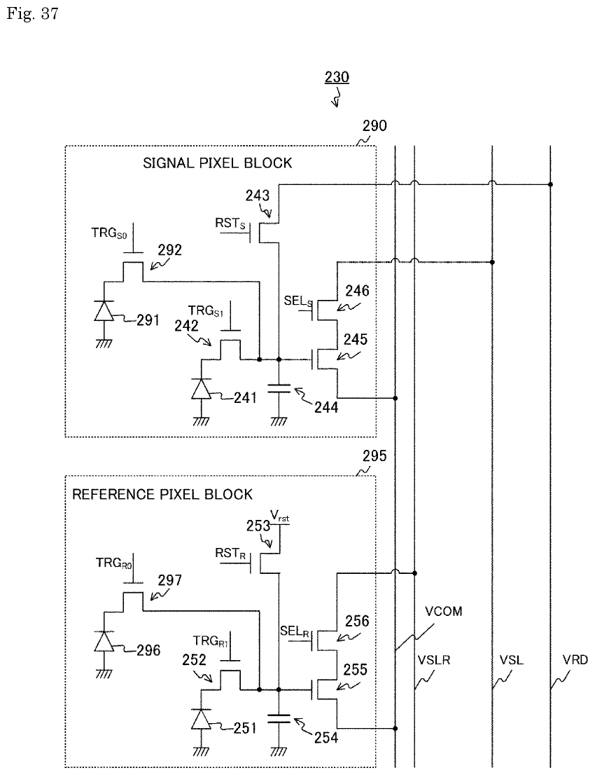

FIG. 37 is a circuit diagram illustrating a configuration example of a pixel array unit 230 according to the eighth embodiment of the present technology. A predetermined number of signal pixel blocks 290 and a predetermined number of reference pixel blocks 295 are arranged in the pixel array unit 230 of the eighth embodiment. A plurality of signal pixels that share an FD are arranged in a signal pixel block 290, and a plurality of reference pixels that share an FD are arranged in a reference pixel block 295.

For example, the signal pixel block 290 includes a photodiode 241, a transfer transistor 242, a reset transistor 243, a floating diffusion region 244, an amplifier transistor 245, and a selector transistor 246. The signal pixel block 290 further includes a photodiode 291 and a transfer transistor 292.

The transfer transistor 292 transfers the charge from the photodiode 291 to the floating diffusion region 244 according to a drive signal TRG_{S0}. The transfer transistor 242 transfers the charge from the photodiode 241 to the floating diffusion region 244 according to a drive signal TRG_{S1}.

With the above-described circuit configuration, the signal pixel block 290 functions as two signal pixels that share the floating diffusion region 244.

The reference pixel block 295 includes a photodiode 251, a transfer transistor 252, a reset transistor 253, a floating diffusion region 254, an amplifier transistor 255, and a selector transistor 256. The reference pixel block 295 further includes a photodiode 296 and a transfer transistor 297.

The transfer transistor 297 transfers the charge from the photodiode 296 to the floating diffusion region 254 according to a drive signal TRG_{R0}. The transfer transistor 252 transfers the charge from the photodiode 251 to the floating diffusion region 254 according to a drive signal TRG_{R1}.

With the above-described circuit configuration, the reference pixel block 295 functions as two reference pixels that share the floating diffusion region 254.

The number of pixels that share the FD is not limited to 2 pixels, and may be, for example, 4 pixels consisting of 2 rows×2 columns, or 8 pixels consisting of 2 rows×4 columns or 4 rows×2 columns.

Each of the second to seventh embodiments can be applied to the eighth embodiment.

As described above, according to the eighth embodiment of the present technology, a plurality of pixels share an FD, so that the number of elements per pixel can be reduced as compared to the case where the FD is not shared.

### 9. Ninth Embodiment

In the first embodiment described above, one reset transistor is arranged for each pixel and the signal pixel 240 is connected to the reset bias line VRD. However, with this configuration, it is difficult to reduce the number of wiring lines. A CMOS image sensor 200 according to a ninth embodiment differs from that according to the first embodiment in that two reset transistors are arranged for each pixel and the reset bias line VRD is eliminated.

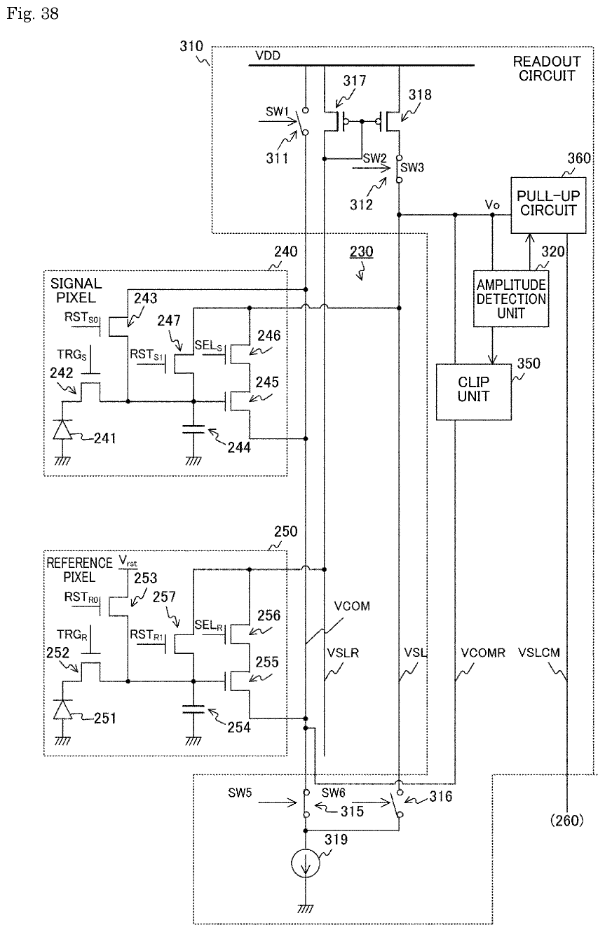

FIG. 38 is a circuit diagram illustrating a configuration example of a pixel array unit 230 and a readout circuit 310 according to the ninth embodiment of the present technology. The signal pixel 240 of the ninth embodiment differs from that of the first embodiment in that it further includes a reset transistor 247. The reference pixel 250 of the ninth embodiment differs from that of the first embodiment in that it further includes a reset transistor 257. The reset bias line VRD is not wired in the pixel array unit 230 of the ninth embodiment, and the switches 313 and 314 are also not arranged.

The reset transistor 243 is inserted between the common signal line VCOM and the floating diffusion region 244, and the reset transistor 247 is inserted between the vertical signal line VSL and the floating diffusion region 244. The vertical drive unit 210 supplies a drive signal RST_{S0} to the reset transistor 243 and supplies a drive signal RST_{S1} to the reset transistor 247.

The reset transistor 253 is inserted between the reset power supply voltage Vᵣₛₜ and the floating diffusion region 254, and the reset transistor 257 is inserted between the reference-side vertical signal line VSLR and the floating diffusion region 254. The vertical drive unit 210 supplies a drive signal RST_{R0} to the reset transistor 253 and supplies a drive signal RST_{R1} to the reset transistor 257.

The reset transistors 243 and 247 are examples of first and second reset transistors described in the claims. The reset transistors 253 and 257 are examples of first and second reset transistors described in the claims.

The readout circuit 310 in the same figure is in the state of the differential mode. In the differential mode, the system control unit 220 opens the switches 311 and 316 and closes the switches 312 and 315.

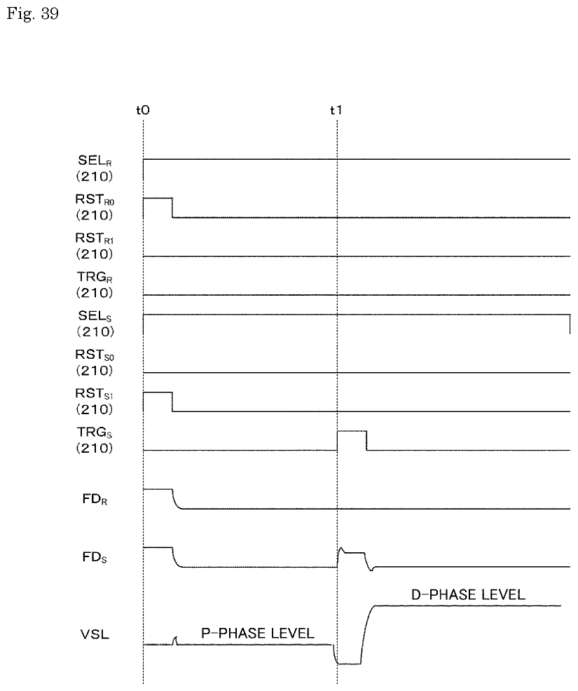

FIG. 39 is a timing chart illustrating an example of a readout operation in the differential mode in the ninth embodiment of the present technology. In the differential mode, the vertical drive unit 210 supplies a drive signal RST_{R0} with high level and a drive signal RST_{S1} with high level over a pulse period from timing t0. On the other hand, a drive signal RST_{R1} and the drive signal RST_{S0} are fixed at low level.

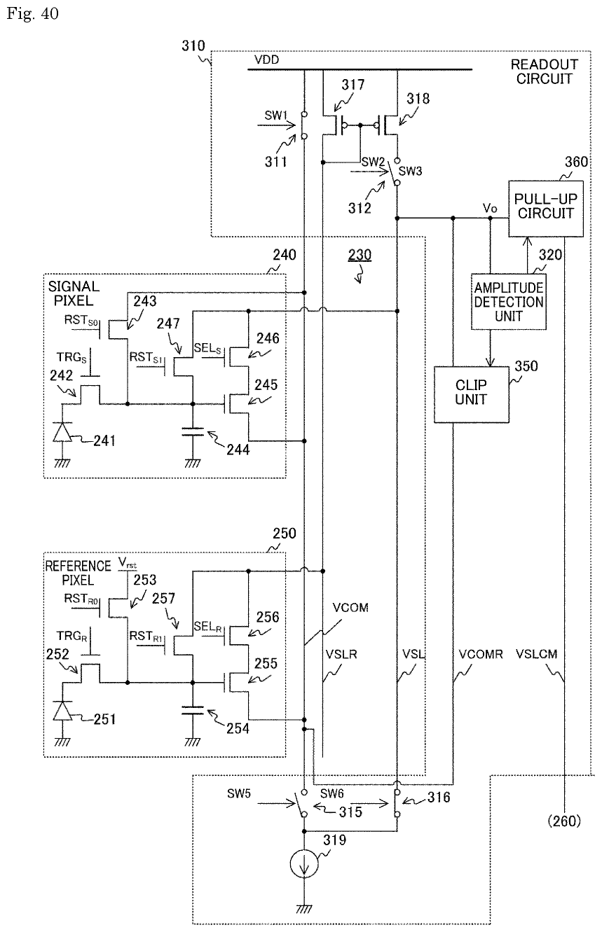

FIG. 40 is a circuit diagram illustrating a state of the readout circuit in the SF mode in the ninth embodiment of the present technology. In the SF mode, the system control unit 220 closes the switches 311 and 316 and opens the switches 312 and 315.

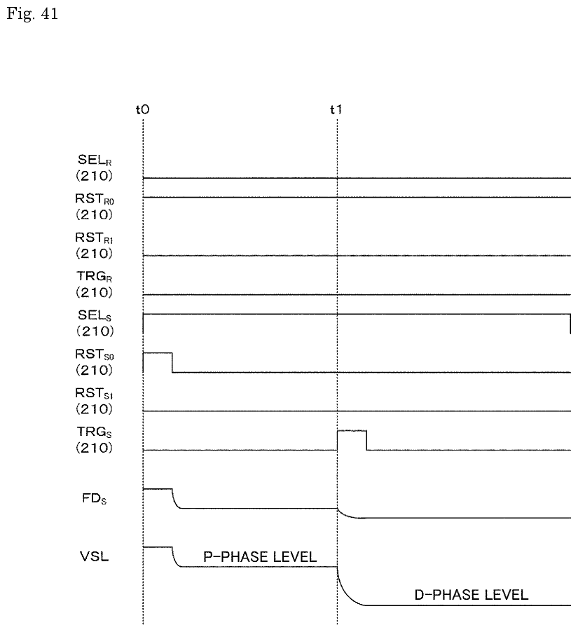

FIG. 41 is a timing chart illustrating an example of a readout operation in the SF mode in the ninth embodiment of the present technology. In the differential mode, the vertical drive unit 210 supplies a drive signal RST_{S0} with high level over a pulse period from timing t0. On the other hand, the drive signal RST_{R0} is fixed at high level, and the drive signals RST_{R1} and RST_{S1} are fixed at low level.

Each of the second to eighth embodiments can be applied to the ninth embodiment.

As described above, according to the ninth embodiment of the present technology, two reset transistors are connected in parallel to the floating diffusion region for each pixel, so that the reset bias line VRD and the switches 313 and 314 can be eliminated.

### 10. Tenth Embodiment

In the above-described ninth embodiment, one vertical signal line VSL is wired for each column, and the column signal processing unit 260 performs AD conversion row by row, but this configuration may have insufficient readout speed. A CMOS image sensor 200 according to a tenth embodiment differs from that according to the ninth embodiment in that a plurality of vertical signal lines are wired for each column and AD conversion is performed simultaneously on a plurality of rows.

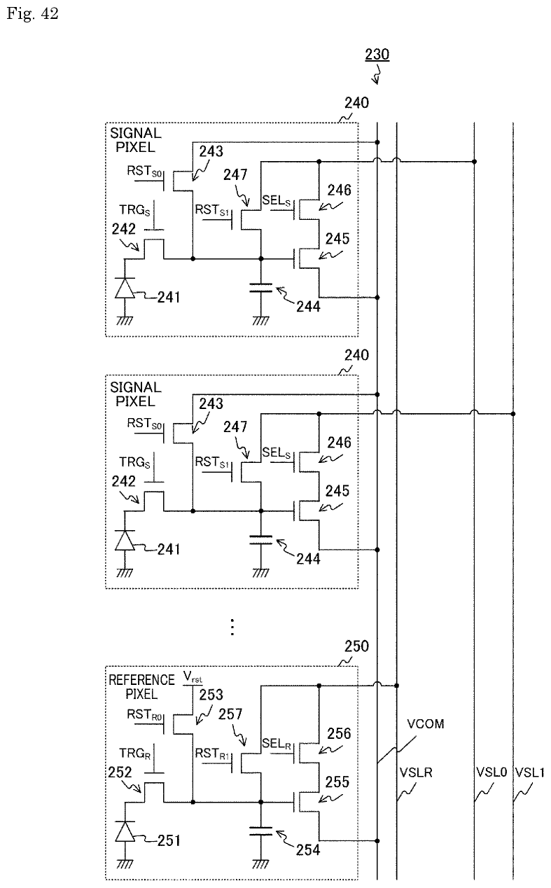

FIG. 42 is a circuit diagram illustrating a configuration example of a pixel array unit 230 according to the tenth embodiment of the present technology. The pixel array unit 230 of the tenth embodiment differs from that of the ninth embodiment in that a plurality of vertical signal lines are wired for each column. For example, vertical signal lines VSL0 and VSL1 are wired for each column. The vertical signal lines VSL0 and VSL1 are examples of first and second vertical signal lines described in the claims.

Half of the signal pixels 240 in a column (such as odd rows) are connected to the vertical signal line VSL0, and the remaining signal pixels 240 are connected to the vertical signal line VSL1. The circuit configurations of the signal pixels 240 and the reference pixels 250 of the tenth embodiment are similar to those of the ninth embodiment. The signal pixel 240 connected to the vertical signal line VSL0 is an example of a first pixel described in the claims. The signal pixel 240 connected to the vertical signal line VSL1 is an example of a second pixel described in the claims.

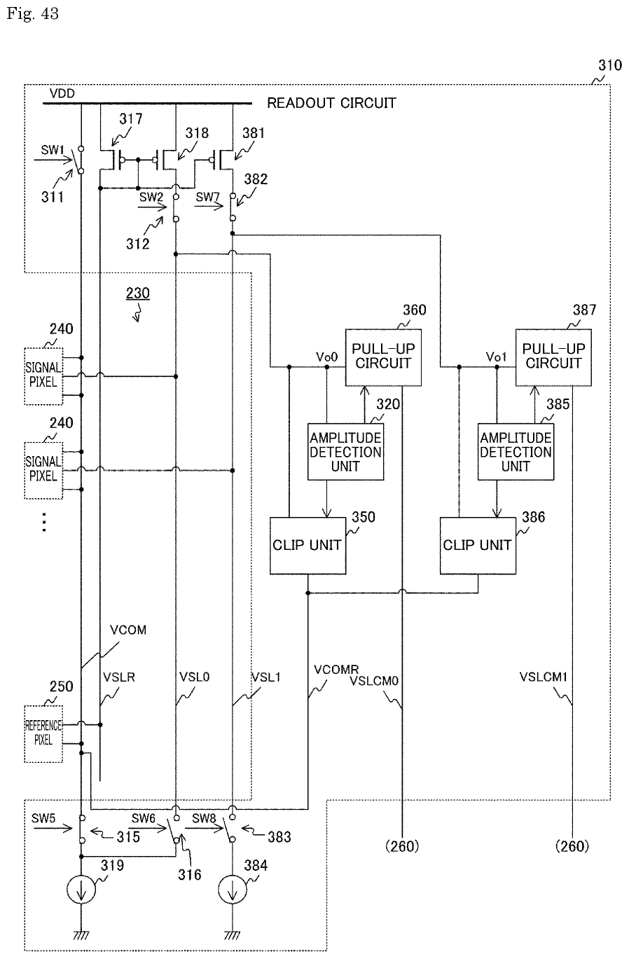

FIG. 43 is a circuit diagram illustrating a configuration example of a readout circuit 310 according to the tenth embodiment of the present technology. The readout circuit 310 of the tenth embodiment further includes a pMOS transistor 381, a switch 382, a switch 383, a tail current source 384, an amplitude detection unit 385, a clip unit 386, and a pull-up circuit 387.

The pMOS transistor 381 is connected in parallel with the pMOS transistor 318 and its gate is connected to the gate and drain of the pMOS transistor 317.

The switch 312 opens and closes the path between the pMOS transistor 318 and the vertical signal line VSL0. The switch 382 opens and closes the path between the pMOS transistor 381 and the vertical signal line VSL1. The switch 383 opens and closes the path between the vertical signal line VSL1 and the tail current source 384.

The amplitude detection unit 320, the clip unit 350, and the pull-up circuit 360 are connected to the vertical signal line VSL0. The amplitude detection unit 385, the clip unit 386, and the pull-up circuit 387 are connected to the vertical signal line VSL1. The clip units 350 and 386 are commonly connected to the reference-side common signal line VCOMR. The pull-up circuit 360 outputs a pixel signal via the comparator-side vertical signal line VSLCM0, and the pull-up circuit 387 outputs a pixel signal via the comparator-side vertical signal line VSLCM1.

Two ADCs (not illustrated) are arranged for each column in the column signal processing unit 260 to perform AD conversion simultaneously on two rows. As a result, the readout speed is improved as compared to the case where AD conversion is performed row by row.

Although two vertical signal lines are wired for each column and two rows are read out simultaneously, three or more (such as four) vertical signal lines may be wired for each column and three or more rows may be read out simultaneously. In this case, circuits for the number of vertical signal lines are added to the readout circuit 310.

As described above, according to the tenth embodiment of the present technology, a plurality of vertical signal lines are wired for each column, and AD conversion is performed simultaneously on a plurality of rows, so that the readout speed can be improved.

### 11. Example of Application to Moving Body

The technology according to the present disclosure (the present technology) can be applied to various products. For example, the technology according to the present disclosure may be realized as a device mounted on any type of moving body such as an automobile, an electric vehicle, a hybrid electric vehicle, a motorcycle, a bicycle, a personal mobility device, an airplane, a drone, a ship, and a robot.

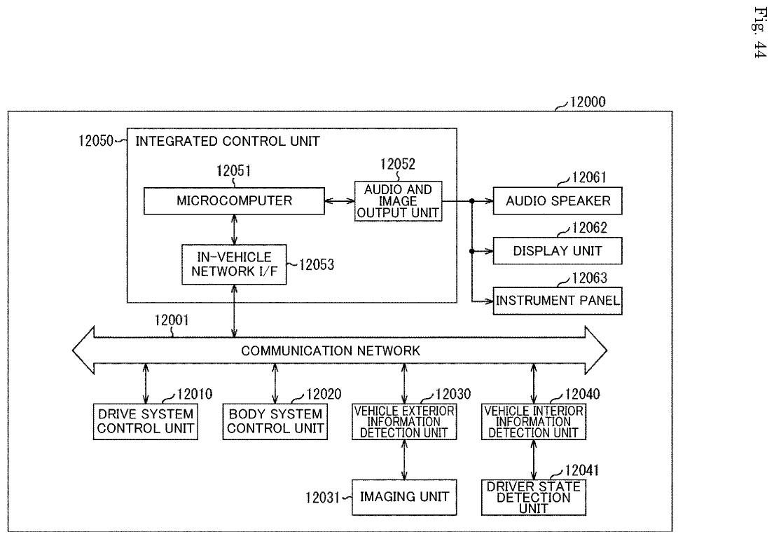

FIG. 44 is a block diagram illustrating a schematic configuration example of a vehicle control system, which is an example of a moving body control system to which the technology according to the present disclosure can be applied.

The vehicle control system 12000 includes a plurality of electronic control units connected thereto via a communication network 12001. In the example illustrated in FIG. 44, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, an audio and image output unit 12052, and an in-vehicle network interface (I/F) 12053 are illustrated.

The drive system control unit 12010 controls an operation of a device related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control device such as a braking device that generates a braking force of a vehicle.

The body system control unit 12020 controls operations of various devices equipped in a vehicle body in accordance with various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generator, the steering mechanism, or the braking device on the basis of information inside and outside the vehicle acquired by the vehicle exterior information detection unit 12030 or the vehicle interior information detection unit 12040, and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio and image output unit 12052 transmits an output signal of at least one of an audio and an image to an output device capable of notifying an occupant of the vehicle or the outside of the vehicle of information visually or audibly. In the example of FIG. 44, an audio speaker 12061, a display unit 12062, and an instrument panel 12063 are illustrated as examples of the output device. The display unit 12062 may include at least one of an on-board display and a head-up display, for example.

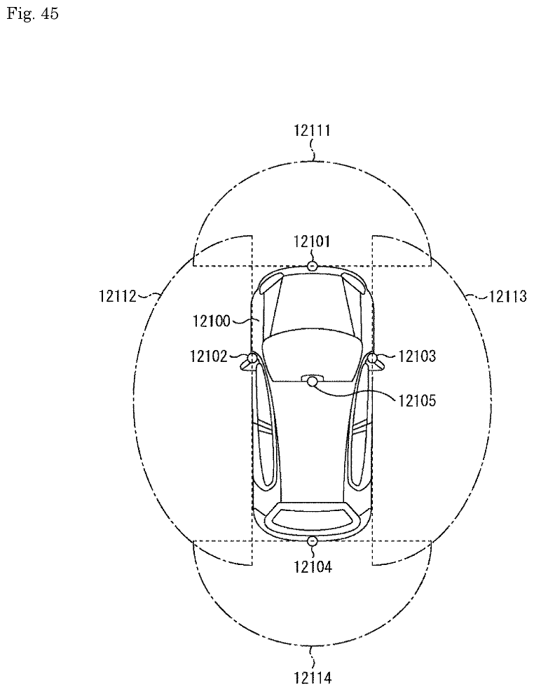

FIG. 45 is a diagram illustrating an example of installation positions of imaging units 12031.

In FIG. 45, imaging units 12101, 12102, 12103, 12104, and 12105 are provided as the imaging units 12031.

The imaging units 12101, 12102, 12103, 12104, and 12105 are provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of the front of the vehicle 12100. The imaging units 12102 and 12103 provided on the side-view mirrors mainly acquire images of a lateral side of the vehicle 12100. The imaging unit 12104 provided on the rear bumper or the back door mainly acquires images of the rear of the vehicle 12100. The imaging unit 12105 provided in the upper portion of the windshield in the vehicle interior is mainly used for detection of preceding vehicles, pedestrians, obstacles, traffic signals, traffic signs, lanes, and the like.

FIG. 45 illustrates an example of imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, a bird's-eye view image of the vehicle 12100 as viewed from above can be obtained by superimposing pieces of image data captured by the imaging units 12101 to 12104.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (for example, 0 km/h or higher) in the substantially same direction as the vehicle 12100, as a preceding vehicle by acquiring a distance to each of three-dimensional objects in the imaging ranges 12111 to 12114 and temporal change in the distance (a relative speed with respect to the vehicle 12100) on the basis of the distance information obtained from the imaging units 12101 to 12104. Further, the microcomputer 12051 can set an inter-vehicle distance which should be secured in front of the vehicle in advance with respect to the preceding vehicle and can perform automated brake control (also including following stop control) or automated acceleration control (also including following start control). In this way, it is possible to perform cooperative control for the purpose of automated driving or the like in which a vehicle autonomously travels without depending on operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the audio and image output unit 12052 controls the display unit 12062 so that a square contour line for emphasis is superimposed and displayed with the recognized pedestrian. In addition, the audio and image output unit 12052 may control the display unit 12062 so that an icon indicating a pedestrian or the like is displayed at a desired position.

An example of the vehicle control system to which the technology according to the present disclosure can be applied has been described above. The technology according to the present disclosure can be applied, for example, to each imaging unit 12031 among the components described above. Specifically, the CMOS image sensor 200 of FIG. 2 can be applied to the imaging unit 12031. By applying the technology according to the present disclosure to the imaging unit 12031, the dynamic range can be extended, a clearer captured image can be obtained, and thus it is possible to reduce a driver's fatigue.

The above-described embodiments provide examples for embodying the present technology, and matters in the embodiments and matters specifying the invention in the claims have a corresponding relationship with each other. Similarly, the matters specifying the invention in the claims and the matters in the embodiments of the present technology having the same name have a corresponding relationship with each other. However, the present technology is not limited to the embodiments and can be embodied by applying various modifications to the embodiments without departing from the gist thereof.

The effects described in the present specification are merely examples and are not intended as limiting, and other effects may be obtained.

The present technology can also have the following configurations.

(1) A solid-state imaging element including: an amplitude detection unit that detects whether an output voltage that is a voltage of a vertical signal line for transmitting either a reset level at which a pixel is initialized or a signal level corresponding to an amount of light exceeds a predetermined determination threshold; and
a black spot prevention unit that controls, when the output voltage exceeds the determination threshold, a first digital signal obtained by converting the reset level and a second digital signal by converting the signal level to different values.

(2) The solid-state imaging element according to (1), wherein the black spot prevention unit includes
a clip unit that limits the output voltage to a value that does not exceed a predetermined clip level, and
a pull-up circuit that controls, when the output voltage exceeds the determination threshold, the voltage to a value higher than the clip level within a period in which the signal level is converted.

(3) The solid-state imaging element according to (2), wherein when the output voltage exceeds the determination threshold, the clip unit limits the output voltage to a value that does not exceed the clip level.

(4) The solid-state imaging element according to (2), wherein when enabled, the clip unit limits the output voltage to a value that does not exceed the clip level.

(5) The solid-state imaging element according to any one of (2) to (4), wherein the pixel includes a signal pixel and a reference pixel that perform differential amplification, and
the clip unit is connected to a common signal line to which the signal pixel and the reference pixel are commonly connected.

(6) The solid-state imaging element according to (5), wherein the clip unit is connected to a node in the common signal line in the vicinity of the reference pixel.

(7) The solid-state imaging element according to (1), wherein the black spot prevention unit includes
a clip unit that limits the output voltage to a value that does not exceed a predetermined clip level, and
a count control unit that controls, when the output voltage exceeds the determination threshold, the second digital signal to a predetermined code.

(8) The solid-state imaging element according to (1), wherein the black spot prevention unit includes a pull-up circuit that controls, when the output voltage exceeds the determination threshold, the voltage to a value higher than the clip level within a period in which the signal level is converted.

(9) The solid-state imaging element according to (1), wherein the black spot prevention unit includes a clip unit that limits the output voltage to a value that does not exceed a predetermined clip level.

(10) The solid-state imaging element according to any one of (1) to (9), wherein the amplitude detection unit includes
a capacitive element connected to a predetermined first node,
a detector transistor that supplies a current to the first node when the output voltage exceeds a predetermined determination threshold, and
a positive feedback logic unit that inverts a voltage of the first node and outputs the resulting voltage from a second node, and controls the voltage of the first node to a predetermined power supply voltage when a voltage of the second node is inverted.

(11) The solid-state imaging element according to any one of (1) to (9), wherein the amplitude detection unit includes
a capacitive element connected to a predetermined first node,
a detector transistor that supplies a current to the first node when the output voltage exceeds the determination threshold, and
a logic gate that inverts a voltage of the first node and outputs the resulting voltage from a second node.

(12) The solid-state imaging element according to any one of (1) to (11), wherein the pixel includes
a photodiode that generates a charge by photoelectric conversion,
a transfer transistor that transfers the charge from the photodiode to a floating diffusion region, and
a first reset transistor that initializes the floating diffusion region.

(13) The solid-state imaging element according to (12), wherein the pixel further includes a second reset transistor connected in parallel with the first reset transistor.

(14) The solid-state imaging element according to (13), wherein
first and second vertical signal lines are wired in each of a predetermined number of columns,
a first pixel in the column is connected to the first vertical signal line, and
a second pixel in the column is connected to the second vertical signal line.

(15) The solid-state imaging element according to claim 15, wherein
third and fourth vertical signal lines are wired in each of the columns,
a third pixel in the column is connected to the third vertical signal line, and
a fourth pixel in the column is connected to the fourth vertical signal line.

(16) The solid-state imaging element according to any one of (1) to (15), wherein a predetermined number of the pixels are connected to the vertical signal line, and
a plurality of pixels among the predetermined number of the pixels share a floating diffusion region.

(17) An electronic device including:
an amplitude detection unit that detects whether an output voltage that is a voltage of a vertical signal line for transmitting either a reset level at which a pixel is initialized or a signal level corresponding to an amount of light exceeds a predetermined determination threshold;
a black spot prevention unit that controls, when the output voltage exceeds the determination threshold, a first digital signal obtained by converting the reset level and a second digital signal obtained by converting the signal level to different values; and
a column signal processing unit that obtains a difference between the first digital signal and the second digital signal.

(18) A method for controlling a solid-state imaging element, including:
an amplitude detection step of detecting whether an output voltage that is a voltage of a vertical signal line for transmitting either a reset level at which a pixel is initialized or a signal level corresponding to an amount of light exceeds a predetermined determination threshold; and
a black spot prevention step of controlling, when the output voltage exceeds the determination threshold, a first digital signal obtained by converting the reset level and a second digital signal obtained by converting the signal level to different values.

### REFERENCE SIGNS LIST

100 Electronic device
110 Imaging lens
120 Digital signal processor
130 Frame memory
140 Recording device
150 Display device
160 Power supply circuit
170 Operation circuit
180 Bus
200 CMOS image sensor
201 Pixel substrate
202 Support substrate
210 Vertical drive unit
220 System control unit
230 Pixel array unit
240 Signal pixel
241, 251, 291, 296 Photodiode
242, 252, 292, 297 Transfer transistor
243, 247, 253, 257 Reset transistor
244, 254 Floating diffusion region
245, 255 Amplifier transistor
246, 256 Selector transistor
250 Reference pixel
260 Column signal processing unit
261 Ramp signal generator circuit
262, 263, 324 Capacitive element
264 Comparator
265 Counter
266 Data holding unit
267, 268 Column ADC
270 Horizontal drive unit
280 Signal processing unit
290 Signal pixel block
295 Reference pixel block
300 Column Readout circuit unit
301, 302 Column Readout circuit
310 Readout circuit
311 to 316, 321, 382, 382 Switch
317, 318, 322, 323, 331, 332, 351, 352, 362, 364, 371, 381 pMOS transistor
319, 384 Tail current source
320, 385 Amplitude detection unit
330 Positive feedback logic unit
333, 353, 372 nMOS transistor
334 NAND (logical NAND) gate
340 Black spot prevention unit
350, 386 Clip unit
360, 387 Pull-up circuit
361 NOR (logical OR) gate
363 Inverter
370 Count control unit
373 AND (logical AND) gate
374 OR (logical OR) gate
501 Photoelectric conversion layer
502 Wiring layer
12031 Imaging unit

1. A solid-state imaging element comprising:
an amplitude detection unit that detects whether an output voltage that is a voltage of a vertical signal line for transmitting either a reset level at which a pixel is initialized or a signal level corresponding to an amount of light exceeds a predetermined determination threshold; and
a black spot prevention unit that controls, when the output voltage exceeds the determination threshold, a first digital signal obtained by converting the reset level and a second digital signal by converting the signal level to different values.

2. The solid-state imaging element according to claim 1, wherein the black spot prevention unit includes
a clip unit that limits the output voltage to a value that does not exceed a predetermined clip level, and
a pull-up circuit that controls, when the output voltage exceeds the determination threshold, the voltage to a value higher than the clip level within a period in which the signal level is converted.

3. The solid-state imaging element according to claim 2, wherein when the output voltage exceeds the determination threshold, the clip unit limits the output voltage to a value that does not exceed the clip level.

4. The solid-state imaging element according to claim 2, wherein when enabled, the clip unit limits the output voltage to a value that does not exceed the clip level.

5. The solid-state imaging element according to claim 2, wherein
the pixel includes a signal pixel and a reference pixel that perform differential amplification, and
the clip unit is connected to a common signal line to which the signal pixel and the reference pixel are commonly connected.

6. The solid-state imaging element according to claim 5, wherein the clip unit is connected to a node in the common signal line in the vicinity of the reference pixel.

7. The solid-state imaging element according to claim 1, wherein the black spot prevention unit includes
a clip unit that limits the output voltage to a value that does not exceed a predetermined clip level, and
a count control unit that controls, when the output voltage exceeds the determination threshold, the second digital signal to a predetermined code.

8. The solid-state imaging element according to claim 1, wherein the black spot prevention unit includes a pull-up circuit that controls, when the output voltage exceeds the determination threshold, the voltage to a value higher than the clip level within a period in which the signal level is converted.

9. The solid-state imaging element according to claim 1, wherein the black spot prevention unit includes a clip unit that limits the output voltage to a value that does not exceed a predetermined clip level.

10. The solid-state imaging element according to claim 1, wherein the amplitude detection unit includes
a capacitive element connected to a predetermined first node,
a detector transistor that supplies a current to the first node when the output voltage exceeds a predetermined determination threshold, and
a positive feedback logic unit that inverts a voltage of the first node and outputs the resulting voltage from a second node, and controls the voltage of the first node to a predetermined power supply voltage when a voltage of the second node is inverted.

11. The solid-state imaging element according to claim 1, wherein the amplitude detection unit includes
a capacitive element connected to a predetermined first node,
a detector transistor that supplies a current to the first node when the output voltage exceeds the determination threshold, and
a logic gate that inverts a voltage of the first node and outputs the resulting voltage from a second node.

12. The solid-state imaging element according to claim 1, wherein the pixel includes a photodiode that generates a charge by photoelectric conversion,
a transfer transistor that transfers the charge from the photodiode to a floating diffusion region, and
a first reset transistor that initializes the floating diffusion region.

13. The solid-state imaging element according to claim 12, wherein the pixel further includes a second reset transistor connected in parallel with the first reset transistor.

14. The solid-state imaging element according to claim 13, wherein
first and second vertical signal lines are wired in each of a predetermined number of columns,
a first pixel in the column is connected to the first vertical signal line, and
a second pixel in the column is connected to the second vertical signal line.

15. The solid-state imaging element according to claim 15, wherein
third and fourth vertical signal lines are wired in each of the columns,
a third pixel in the column is connected to the third vertical signal line, and
a fourth pixel in the column is connected to the fourth vertical signal line.

16. The solid-state imaging element according to claim 1, wherein
a predetermined number of the pixels are connected to the vertical signal line, and
a plurality of pixels among the predetermined number of the pixels share a floating diffusion region.

17. An electronic device comprising:
an amplitude detection unit that detects whether an output voltage that is a voltage of a vertical signal line for transmitting either a reset level at which a pixel is initialized or a signal level corresponding to an amount of light exceeds a predetermined determination threshold;
a black spot prevention unit that controls, when the output voltage exceeds the determination threshold, a first digital signal obtained by converting the reset level and a second digital signal obtained by converting the signal level to different values; and
a column signal processing unit that obtains a difference between the first digital signal and the second digital signal.

18. A method for controlling a solid-state imaging element, comprising:
an amplitude detection step of detecting whether an output voltage that is a voltage of a vertical signal line for transmitting either a reset level at which a pixel is initialized or a signal level corresponding to an amount of light exceeds a predetermined determination threshold; and
a black spot prevention step of controlling, when the output voltage exceeds the determination threshold, a first digital signal obtained by converting the reset level and a second digital signal obtained by converting the signal level to different values.
